(19) United States
(12) Patent Application Publication
(10) Pub. No.: US 2012/0084618 A1
(43) Pub. Date: Apr. 5, 2012

(54) JOINTLY ENCODING A SCHEDULING REQUEST INDICATOR AND ACKNOWLEDGMENTS/NEGATIVE ACKNOWLEDGMENTS

(75) Inventors: Sayantan Choudhury, Vancouver, WA (US); Zhanping Yin, Vancouver, WA (US)

(73) Assignee: Sharp Laboratories of America, Inc., Camas, WA (US)

(21) Appl. No.: 12/896,785

(22) Filed: Oct. 1, 2010

(51) Int. Cl. H03M 13/05; G06F 11/10

(52) U.S. Cl. 714/752; 714/E11.032

(57) ABSTRACT

A User Equipment (UE) configured for jointly encoding a Scheduling Request Indicator (SRI) and Acknowledgments/Negative Acknowledgments (ACK/NACKs) is disclosed. The UE includes a processor and instructions stored in memory. The UE generates a Scheduling Request Indicator (SRI) bit and a plurality of Acknowledgement/Negative Acknowledgement (ACK/NACK) bits. The UE also encodes the SRI bit and the plurality of ACK/NACK bits with unequal error protection to generate a jointly-encoded SRI and ACK/NACK message and transmits the jointly-encoded SRI and ACK/NACK message.

### TECHNICAL FIELD

The present disclosure relates generally to communication systems. More specifically, the present disclosure relates to jointly encoding a Scheduling Request Indicator (SRI) and Acknowledgments/Negative Acknowledgments (ACK/NACKs).

### BACKGROUND

Wireless communication devices have become smaller and more powerful in order to meet consumer needs and to improve portability and convenience. Consumers have become dependent upon wireless communication devices and have come to expect reliable service, expanded areas of coverage, and increased functionality. A wireless communication system may provide communication for a number of cells, each of which may be serviced by a base station. A base station may be a fixed station that communicates with wireless communication devices.

As wireless communication devices have advanced, improvements in communication quality have been sought. One way to increase communication quality is to use an Acknowledgment/Negative Acknowledgment (ACK/NACK) scheme. For example, a NACK may indicate a failure in the correct reception of information, allowing a retransmission of the incorrectly received information.

Wireless communication devices and base stations may communicate several different kinds of control information, such as the ACK/NACKs described above. Scheduling requests are another kind of control information. Errors may occur in the transmission and/or reception of control information. As illustrated by this discussion, improved systems and methods for formatting control information may be beneficial.

### BRIEF DESCRIPTION OF THE DRAWINGS

FIG. 1 is a block diagram illustrating one configuration of a User Equipment (UE) in which systems and methods for jointly encoding a Scheduling Request Indicator (SRI) and Acknowledgments/Negative Acknowledgments (ACK/NACKs) may be implemented;

FIG. 2 is a block diagram illustrating another configuration of a User Equipment (UE) in which systems and methods for jointly encoding a Scheduling Request Indicator (SRI) and Acknowledgments/Negative Acknowledgments (ACK/NACKs) may be implemented;

FIG. 3 is a flow diagram illustrating one configuration of a method for jointly encoding a Scheduling Request Indicator (SRI) and Acknowledgments/Negative Acknowledgments (ACK/NACKs);

FIG. 4 is a block diagram illustrating one configuration of a joint Scheduling Request Indicator (SRI) and Acknowledgment/Negative Acknowledgment (ACK/NACK) encoding module;

FIG. 5 is a flow diagram illustrating a more specific configuration of a method for jointly encoding a Scheduling Request Indicator (SRI) and Acknowledgments/Negative Acknowledgments (ACK/NACKs);

FIG. 6 is a block diagram illustrating another configuration of a joint Scheduling Request Indicator (SRI) and Acknowledgment/Negative Acknowledgment (ACK/NACK) encoding module;

FIG. 7 is a flow diagram illustrating another more specific configuration of a method for jointly encoding a Scheduling Request Indicator (SRI) and Acknowledgments/Negative Acknowledgments (ACK/NACKs);

FIG. 8 is a block diagram illustrating another configuration of a joint Scheduling Request Indicator (SRI) and Acknowledgment/Negative Acknowledgment (ACK/NACK) encoding module;

FIG. 9 is a flow diagram illustrating another more specific configuration of a method for jointly encoding a Scheduling Request Indicator (SRI) and Acknowledgments/Negative Acknowledgments (ACK/NACKs);

FIG. 10 is a diagram illustrating one example of a jointly-encoded Scheduling Request Indicator (SRI) and Acknowledgment/Negative Acknowledgment (ACK/NACK) message;

FIG. 11 is a block diagram illustrating another configuration of a joint Scheduling Request Indicator (SRI) and Acknowledgment/Negative Acknowledgment (ACK/NACK) encoding module;

FIG. 12 is a flow diagram illustrating another more specific configuration of a method for jointly encoding a Scheduling Request Indicator (SRI) and Acknowledgments/Negative Acknowledgments (ACK/NACKs);

FIG. 13 is a diagram illustrating one example of a jointly-encoded Scheduling Request Indicator (SRI) and Acknowledgment/Negative Acknowledgment (ACK/NACK) message;

FIG. 14 is a flow diagram illustrating one configuration of a method for decoding a jointly-encoded Scheduling Request Indicator (SRI) and Acknowledgment/Negative Acknowledgment (ACK/NACK) message;

FIG. 15 illustrates various components that may be utilized in a User Equipment (UE); and

FIG. 16 illustrates various components that may be utilized in a Node B.

### DETAILED DESCRIPTION

The 3rd Generation Partnership Project, also referred to as “3GPP,” is a collaboration agreement that aims to define globally applicable technical specifications and technical reports for third and fourth generation wireless communication systems. The 3GPP may define specifications for the next generation mobile networks, systems, and devices.

3GPP Long Term Evolution (LTE) is the name given to a project to improve the Universal Mobile Telecommunications System (UMTS) mobile phone or device standard to cope with future requirements. In one aspect, UMTS has been modified to provide support and specification for the Evolved Universal Terrestrial Radio Access (E-UTRA) and Evolved Universal Terrestrial Radio Access Network (E-UTRAN).

At least some aspects of the systems and methods disclosed herein may be described in relation to the 3GPP LTE and LTE-Advanced standards (e.g., Release-8 and Release-10). However, the scope of the present disclosure should not be limited in this regard. At least some aspects of the systems and methods disclosed herein may be utilized in other types of wireless communication systems.

A wireless communication device may be an electronic device used to communicate voice and/or data to a base station, which in turn may communicate with a network of devices (e.g., public switched telephone network (PSTN), the Internet, etc.). In describing systems and methods herein, a wireless communication device may alternatively be referred to as a mobile station, a user equipment (UE), an access terminal, a subscriber station, a mobile terminal, a remote station, a user terminal, a terminal, a subscriber unit, a mobile device, etc. A wireless communication device may be a cellular phone, a smart phone, a personal digital assistant (PDA), a laptop computer, a netbook, an e-reader, a wireless modem, etc. In 3GPP specifications, a wireless communication device is typically referred to as a user equipment (UE). However, as the scope of the present disclosure should not be limited to the 3GPP standards, the terms “UE” and “wireless communication device” may be used interchangeably herein to mean the more general term “wireless communication device.”

In 3GPP specifications, a base station is typically referred to as a Node B, an evolved or enhanced Node B (eNB), a home enhanced or evolved Node B (HeNB) or some other similar terminology. As the scope of the disclosure should not be limited to 3GPP standards, the terms “base station,” “Node B,” “eNB,” and “HeNB” may be used interchangeably herein to mean the more general term “base station.” Furthermore, the term “base station” may be used to denote an access point. An access point may be an electronic device that provides access to a network (e.g., Local Area Network (LAN), the Internet, etc.) for wireless communication devices. The term “communication device” may be used to denote both a wireless communication device and/or a base station.

The term “simultaneous” may be used herein to denote a situation where two or more events occur in overlapping time frames. In other words, two “simultaneous” events may overlap in time to some extent, but are not necessarily of the same duration. Furthermore, simultaneous events may or may not begin or end at the same time.

A User Equipment (UE) configured for jointly encoding a Scheduling Request Indicator (SRI) and Acknowledgments/Negative Acknowledgments (ACK/NACKs) is disclosed. The UE includes a processor and instructions stored in memory. The UE generates a Scheduling Request Indicator (SRI) bit and a plurality of Acknowledgement/Negative Acknowledgement (ACK/NACK) bits. The UE also encodes the SRI bit and the plurality of ACK/NACK bits with unequal error protection to generate a jointly-encoded SRI and ACK/NACK message and transmits the jointly-encoded SRI and ACK/NACK message.

Unequal error protection may be provided by providing more protection to the SRI bit than to each of the ACK/NACK bits. Unequal error protection may be provided by providing more protection to each of the ACK/NACK bits than to the SRI bit.

Encoding the SRI bit and the plurality of ACK/NACK bits may include encoding the SRI bit to produce a number of encoded SRI bits and encoding the encoded SRI bits and the plurality of ACK/NACK bits using a Reed-Muller encoder. The SRI bit may be encoded using repetition encoding. The SRI bit may be encoded using Reed-Muller encoding.

Encoding the SRI bit and the plurality of ACK/NACK bits may include encoding the SRI bit to produce a number of encoded SRI bits, encoding the plurality of ACK/NACK bits using a Reed-Muller encoder to produce encoded ACK/NACK bits and combining the encoded SRI bits and the encoded ACK/NACK bits. The SRI bit may be encoded using repetition encoding. The SRI bit may be encoded using Reed-Muller encoding.

Encoding the SRI bit and the plurality of ACK/NACK bits may include encoding the SRI bit to produce a number of encoded SRI bits, encoding the plurality of ACK/NACK bits using a Reed-Muller encoder to produce encoded ACK/NACK bits and combining the encoded SRI bits and the encoded ACK/NACK bits by placing one or more encoded SRI bits in place of one or more generated repeated parity bits or in place of one or more repeated parity bits that are not generated. The SRI bit may be encoded using repetition encoding. The SRI bit may be encoded using Reed-Muller encoding.

Encoding the SRI bit and the plurality of ACK/NACK bits may include encoding the plurality of ACK/NACK bits using a Reed-Muller encoder to produce encoded ACK/NACK bits with repeated parity bits, determining whether the SRI bit indicates a Scheduling Request (SR) and inverting a number of the repeated parity bits if the SRI bit indicates an SR.

A Node B for decoding a jointly-encoded Scheduling Request Indicator (SRI) and Acknowledgment/Negative Acknowledgment (ACK/NACK) message is also disclosed. The Node B includes a processor and instructions stored in memory. The Node B receives a jointly-encoded SRI and ACK/NACK message, determines whether the jointly-encoded SRI and ACK/NACK message indicates a scheduling request and inverts a number of repeated parity bits if the jointly-encoded SRI and ACK/NACK message indicates a scheduling request. The Node B also decodes the jointly-encoded SRI and ACK/NACK message.

A method for jointly encoding a Scheduling Request Indicator (SRI) and Acknowledgments/Negative Acknowledgments (ACK/NACKs) is also disclosed. The method includes generating a Scheduling Request Indicator (SRI) bit and a plurality of Acknowledgement/Negative Acknowledgement (ACK/NACK) bits. The method also includes encoding, on a User Equipment (UE), the SRI bit and the plurality of ACK/NACK bits with unequal error protection to generate a jointly-encoded SRI and ACK/NACK message and transmitting the jointly-encoded SRI and ACK/NACK message.

A method for decoding a jointly-encoded Scheduling Request Indicator (SRI) and Acknowledgment/Negative Acknowledgment (ACK/NACK) message is also disclosed. The method includes receiving a jointly-encoded SRI and ACK/NACK message and determining, on a Node B, whether the jointly-encoded SRI and ACK/NACK message indicates a scheduling request. The method also includes inverting, on the Node B, a number of repeated parity bits if the jointly-encoded SRI and ACK/NACK message indicates a scheduling request and decoding the jointly-encoded SRI and ACK/NACK message.

A non-transitory, tangible computer-readable medium for jointly encoding a Scheduling Request Indicator (SRI) and Acknowledgments/Negative Acknowledgments (ACK/NACKs) is also disclosed. The computer-readable medium includes executable instructions for generating a Scheduling Request Indicator (SRI) bit and a plurality of Acknowledgement/Negative Acknowledgement (ACK/NACK) bits. The computer-readable medium also includes executable instructions for encoding the SRI bit and the plurality of ACK/NACK bits with unequal error protection to generate a jointly-encoded SRI and ACK/NACK message and transmitting the jointly-encoded SRI and ACK/NACK message.

A non-transitory, tangible computer-readable medium for decoding a jointly-encoded Scheduling Request Indicator (SRI) and Acknowledgment/Negative Acknowledgment (ACK/NACK) message is also disclosed. The computer-readable medium includes executable instructions for receiving a jointly-encoded SRI and ACK/NACK message and determining whether the jointly-encoded SRI and ACK/NACK message indicates a scheduling request. The computer-readable medium also includes executable instructions for inverting a number of repeated parity bits if the jointly-encoded SRI and ACK/NACK message indicates a scheduling request and decoding the jointly-encoded SRI and ACK/NACK message.

Systems and methods for joint encoding of Acknowledgment/Negative Acknowledgment (ACK/NACK) and Scheduling Request Indicator (SRI) information are disclosed herein. In Long Term Evolution (LTE) Release-8, a UE may need to transmit both an ACK/NACK and Scheduling Request Indicator (SRI) (at the same time or within a period of time, for example). When this occurs, the ACK/NACK may be transmitted on the SRI resource. However, the SRI resource payload size may be limited and hence, it may not be possible to transmit a larger payload size ACK/NACK on the SRI resource. The systems and methods disclosed herein describe different joint encoding approaches for simultaneous transmission of SRI and ACK/NACK for larger payload sizes. In some instances, the SRI information may need to be more reliable than the ACK/NACK. In other instances, the ACK/NACK information may need to be more reliable than the SRI information. Thus, different schemes are described that may provide unequal error protection when comparing SRI error protection to ACK/NACK error protection. Thus, this may provide the benefit that the SRI information is more reliably received than ACK/NACK information or that the ACK/NACK information is more reliably received than the SRI information. That is, a Node B may more reliably receive ACK/NACK information, allowing the Node B to retransmit information to the UE. Or, a Node B may more reliably receive SRI information, thus allowing the Node B to schedule or prepare to schedule resources for the UE.

In the case of a simultaneous ACK/NACK and SRI, one approach involves jointly encoding SRI and uplink (UL) ACK/NACK information. However, a straightforward joint encoding treats each of the bits of ACK/NACK and SRI with equal importance (e.g., with equal reliability, redundancy, etc.). If there is a need to provide more reliability to SRI information (compared to ACK/NACK information) or to ACK/NACK information (compared to SRI information), alternative schemes may need to be considered. For example, one kind of information may be given unequal error protection by providing greater reliability or protection for that information than another kind of information. For instance, an SRI may be given higher reliability by providing more redundancy to the SRI information than the redundancy given to an ACK/NACK. Alternatively, an ACK/NACK may need to be transmitted more reliably than SRI. Hence, SRI may be provided less redundancy than simply jointly encoding both types of information. The systems and methods disclosed herein describe different schemes for unequal error protection for SRI and ACK/NACK.

For example, the systems and methods disclosed herein may use repetition encoding for SRI before jointly encoding the SRI with ACK/NACK. In another configuration, repetition encoding may be used for SRI information and transmitted simultaneously with encoded ACK/NACK bits.

In another configuration, higher-order Reed-Muller encoding may be used. Higher-order Reed-Muller encoding may repeat a portion of the parity bits. For example, “higher-order” Reed-Muller encoding (e.g., (48, O) Reed-Muller encoding instead of (32, O) Reed-Muller encoding typically used for ACK/NACK bits) may take an input of 0 bits and output 48 bits, where 16 bits are repeated. In other words, the first 32 bits may contain encoded information and the last 16 bits may be a repeat of the first 16 bits. Instead of repeating these parity bits, the SRI information may be transmitted in place one or more of those bits. The number of parity bits that are allocated to the SRI controls the reliability of SRI information. Hence, unequal protection may be provided to the SRI compared to ACK/NACK. In other words, a higher number of parity bits may be allocated to SRI encoding to provide greater protection to the SRI than the ACK/NACK. Alternatively, fewer parity bits may be allocated to the SRI information in order to provide greater protection to the ACK/NACK.

In yet another configuration for higher-order Reed-Muller encoding, a portion of the parity bits may be repeated. The scheme may be modified such that when there is no scheduling request (SR) (e.g., a ‘0’ bit for SR), all of the repeated parity bits may be transmitted as normal. However, in the case that an SR is transmitted (e.g., a ‘1’ bit for SR), one or more of the repeated parity bits may be flipped or inverted.

When the systems and methods disclosed herein are not used (in the case of a simultaneous ACK/NACK and SRI), one straightforward approach is to jointly encode SRI and uplink (UL) ACK/NACK information. However, an SRI or Scheduling Request (SR) may be represented by only one bit of information. Thus, this straightforward approach for joint encoding treats each of the bits of ACK/NACK and SRI with equal importance. In order to provide higher or lower reliability to SRI bits compared to ACK/NACK, other approaches may be used as follows.

The SRI may be encoded using repetition encoding (or other encoding, such as Reed Muller encoding, for example) and then jointly encoded with ACK/NACK bits. Furthermore, the encoded (e.g., repeated) SRI bits may be further interleaved to provide maximal diversity and to help prevent burst errors. This scheme may be particularly useful if, for instance, a reduction in the false alarm rate or misdetection rate of SR is desired or if ACK/NACK needs to be transmitted with more reliability than straightforward joint encoding.

Another approach involves the simultaneous transmission of encoded SRI and ACK/NACK. For example, the SRI may be encoded using repetition encoding (e.g., the SRI bit may be repeated a number of times) or Reed-Muller encoding. The ACK/NACK bits may be encoded using a Reed-Muller encoder. Then, the encoded (e.g., repeated) SRI bits may be combined with (e.g., appended to) the encoded ACK/NACK bits. This “jointly-encoded” SRI and ACK/NACK sequence may then be transmitted as a single message.

Yet another approach involves joint encoding using higher-order Reed-Muller encoding with a repetition of SRI bits. For example, (32, O) Reed-Muller encoding may be extended to 48 encoded bits using circular buffer matching. Instead of using a circular buffer, an alternative would to be to transmit the ACK/NACK using (32, O) Reed-Muller encoding and the SRI using one or more of the other 16 encoded bits by using another encoding (e.g., repetition encoding or Reed-Muller encoding). Alternatively, M bits can be used for SRI transmission where M is between 0-16 bits. If M=16, it may be identical to the scenario described above. If M=0, then all the bits are used for ACK/NACK transmission and provides the maximum reliability to ACK/NACK. Hence, by varying M, the reliability of ACK/NACK transmission compared to SRI may be controlled.

Yet another approach involves using higher-order Reed-Muller encoding with inverted repeated parity bits. In this approach, the repeated parity bits (or the 16 circular buffer bits, for example) are transmitted without modification when there is no SR and are inverted or flipped (e.g., 0 becomes 1 and 1 becomes 0) when there is an SR transmission. In this way, the decoder can detect the SR transmission based on the joint detection of SR and ACK/NACK. The decoder may blindly decode under both hypotheses and decide on whether it was a positive SRI. Additionally, the 1 or more SR bits could also be transmitted jointly with the ACK/NACK and the 16 circular buffer bits transmitted as described above. Moreover, in other configurations, more or fewer than 16 circular buffer bits for the (32, O) Reed-Muller encoding (e.g., the last ‘N’ bits) could be transmitted without modification or be inverted or flipped as described above.

One example of an encoding scheme is given for Hybrid Automatic Repeat Request (HARQ) Acknowledgment (ACK) on a Discrete Fourier Transform-spread (DFT-spread) Orthogonal Frequency-Division Multiplexing (OFDM) Physical Uplink Control Channel (PUCCH). The DFT-spread OFDM PUCCH may also be known as a “Format 3” PUCCH, for example.

The bits input to a channel encoding block are denoted by o₀, o₁, o₂, o₃, . . . , o_{O-1}, where O is a number of bits. In one configuration, 0 may be up to 10 bits in the case of no collision (e.g., no simultaneous SRI and ACK/NACK). The message bits o₀, o₁, o₂, o₃, . . . , o_{O-1} are encoded into a block of bits b₀, b₁, b₂, b₃, . . . , b_{B-1}, where B=32, for example.

In the case of joint encoding of ACK/NACK and SRI, 1 bit representing a Scheduling Request (SR) or Scheduling Request Indicator (SRI) is input in addition to the ACK/NACK bits described above. This gives a maximum of 10+1=11 bits of input, for example.

The HARQ-ACK (with SR) on a Format 3 PUCCH may be encoded using (32, O) block encoding (e.g., Reed-Muller encoding). The code words of the (32, O) block encoding are a linear combination of the 11 basis sequences (denoted M_{i,n}) illustrated in Table 1.

TABLE 1

| i | M_{i, 0} | M_{i, 1} | M_{i, 2} | M_{i, 3} | M_{i, 4} | M_{i, 5} | M_{i, 6} | M_{i, 7} | M_{i, 8} | M_{i, 9} | M_{i, 10} |
|---|---|---|---|---|---|---|---|---|---|---|---|
| 0 | 1 | 1 | 0 | 0 | 0 | 0 | 0 | 0 | 0 | 0 | 1 |
| 1 | 1 | 1 | 1 | 0 | 0 | 0 | 0 | 0 | 0 | 1 | 1 |
| 2 | 1 | 0 | 0 | 1 | 0 | 0 | 1 | 0 | 1 | 1 | 1 |
| 3 | 1 | 0 | 1 | 1 | 0 | 0 | 0 | 0 | 1 | 0 | 1 |
| 4 | 1 | 1 | 1 | 1 | 0 | 0 | 0 | 1 | 0 | 0 | 1 |
| 5 | 1 | 1 | 0 | 0 | 1 | 0 | 1 | 1 | 1 | 0 | 1 |
| 6 | 1 | 0 | 1 | 0 | 1 | 0 | 1 | 0 | 1 | 1 | 1 |
| 7 | 1 | 0 | 0 | 1 | 1 | 0 | 0 | 1 | 1 | 0 | 1 |
| 8 | 1 | 1 | 0 | 1 | 1 | 0 | 0 | 1 | 0 | 1 | 1 |
| 9 | 1 | 0 | 1 | 1 | 1 | 0 | 1 | 0 | 0 | 1 | 1 |
| 10 | 1 | 0 | 1 | 0 | 0 | 1 | 1 | 1 | 0 | 1 | 1 |
| 11 | 1 | 1 | 1 | 0 | 0 | 1 | 1 | 0 | 1 | 0 | 1 |
| 12 | 1 | 0 | 0 | 1 | 0 | 1 | 0 | 1 | 1 | 1 | 1 |
| 13 | 1 | 1 | 0 | 1 | 0 | 1 | 0 | 1 | 0 | 1 | 1 |
| 14 | 1 | 0 | 0 | 0 | 1 | 1 | 0 | 1 | 0 | 0 | 1 |
| 15 | 1 | 1 | 0 | 0 | 1 | 1 | 1 | 1 | 0 | 1 | 1 |
| 16 | 1 | 1 | 1 | 0 | 1 | 1 | 1 | 0 | 0 | 1 | 0 |
| 17 | 1 | 0 | 0 | 1 | 1 | 1 | 0 | 0 | 1 | 0 | 0 |
| 18 | 1 | 1 | 0 | 1 | 1 | 1 | 1 | 1 | 0 | 0 | 0 |
| 19 | 1 | 0 | 0 | 0 | 0 | 1 | 1 | 0 | 0 | 0 | 0 |
| 20 | 1 | 0 | 1 | 0 | 0 | 0 | 1 | 0 | 0 | 0 | 1 |
| 21 | 1 | 1 | 0 | 1 | 0 | 0 | 0 | 0 | 0 | 1 | 1 |
| 22 | 1 | 0 | 0 | 0 | 1 | 0 | 0 | 1 | 1 | 0 | 1 |
| 23 | 1 | 1 | 1 | 0 | 1 | 0 | 0 | 0 | 1 | 1 | 1 |
| 24 | 1 | 1 | 1 | 1 | 1 | 0 | 1 | 1 | 1 | 1 | 0 |
| 25 | 1 | 1 | 0 | 0 | 0 | 1 | 1 | 1 | 0 | 0 | 1 |
| 26 | 1 | 0 | 1 | 1 | 0 | 1 | 0 | 0 | 1 | 1 | 0 |
| 27 | 1 | 1 | 1 | 1 | 0 | 1 | 0 | 1 | 1 | 1 | 0 |
| 28 | 1 | 0 | 1 | 0 | 1 | 1 | 1 | 0 | 1 | 0 | 0 |
| 29 | 1 | 0 | 1 | 1 | 1 | 1 | 1 | 1 | 1 | 0 | 0 |
| 30 | 1 | 1 | 1 | 1 | 1 | 1 | 1 | 1 | 1 | 1 | 1 |
| 31 | 1 | 0 | 0 | 0 | 0 | 0 | 0 | 0 | 0 | 0 | 0 |

The encoded HARQ-ACK block is denoted by b₀, b₁, b₂, b₃, . . . , b_{B-1}, where B=32 and

$${b}_{i} = {\sum }_{n = 0}^{O - 1} ( {o}_{n} \cdot {M}_{i , n} ) mod 2 ,$$

where i=0, 1, 2, . . . , B−1. The output bit sequence q₀, q₁, q₂, q₃, . . . , q_{Q}_{_{ACK}}₋₁ is obtained by circular repetition of the encoded HARQ-ACK block as follows: qᵢ=b_{(i mod B)}, where i=0, 1, 2, . . . , Q_{ACK-1}. Q_{ACK} is the total number of encoded bits for the encoded HARQ-ACK (and SR) block, which is equal to 48, for example.

In one configuration of the systems and methods disclosed herein, the above example may be modified as follows. Instead of using circular repetition of the encoded HARQ-ACK (and SR) bits, the encoded bits may be used to represent SR information only. For instance, the input bits are up to 10 ACK/NACK only bits, which are encoded to 32 bits as above. However, none, part or all of the circular repetition may be used for SR representation. If the entire circular repetition is being used for SR, for example, the 16 bits can be an all-1 sequence or all-0 sequence depending on positive or negative SR, respectively.

In another configuration of the systems and methods disclosed herein, the above example may be modified as follows. If there is no SR (e.g., SRI=0), the sequence or representation may be identical to the encoding of up to 10 bits of ACK/NACK information (similar to that described above). However, if there is a positive SR (e.g., SRI=1), one or more of the circular repetition bits (e.g., repeated parity bits) are inverted or flipped. For example, ‘0’ bits are changed to ‘1’ bits and ‘1’ bits are changed to ‘0’ bits for qᵢ, where i=33, . . . , 48. For instance, a decoder can first use the first 16 bits and the last 16 bits from the demodulated data and determine whether it is a positive or negative SR. Then, depending on the decoded SR, the decoder may decode the 48-bit encoded data. For example, the last 16 bits may be inverted (on the decoding side) for decoding if a positive SR is determined. However, if a negative SR is determined, the decoder may decode the 48 bits of encoded data without modification.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods. As used herein the term “plurality” may indicate two or more. For example, a plurality of elements refers to two or more elements.

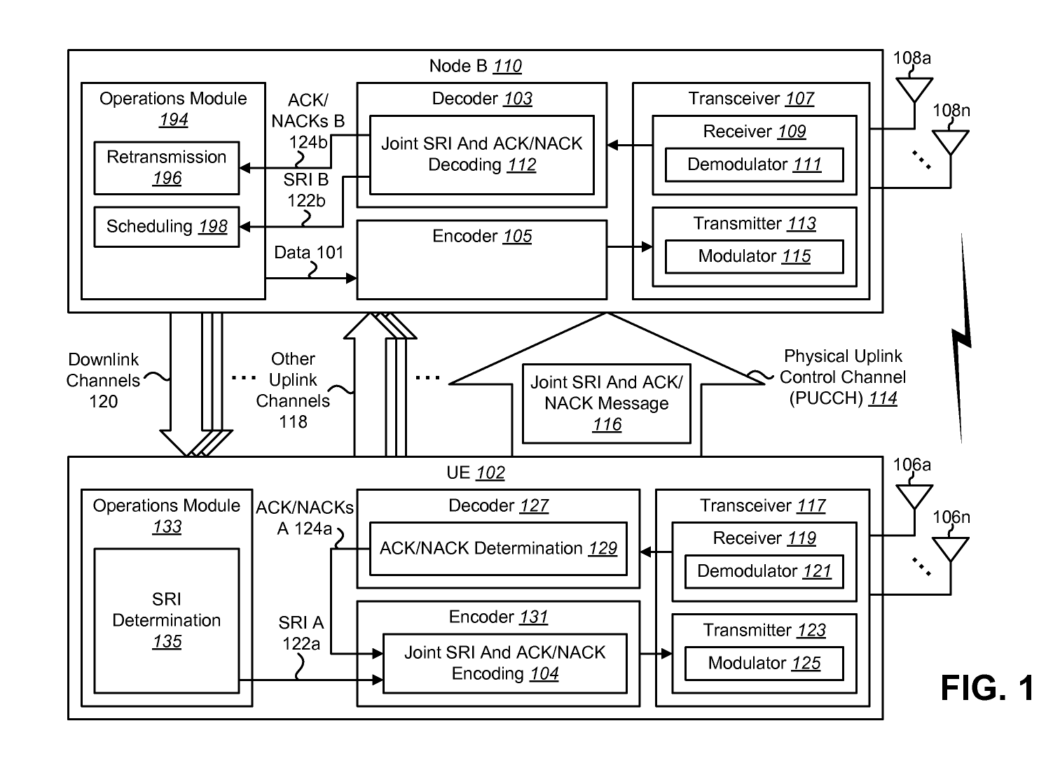

FIG. 1 is a block diagram illustrating one configuration of a User Equipment (UE) 102 in which systems and methods for jointly encoding a Scheduling Request Indicator (SRI) and Acknowledgments/Negative Acknowledgments (ACK/NACKs) may be implemented. The UE 102 communicates with a Node B 110 using one or more antennas 106a-n. For example, the UE 102 transmits electromagnetic signals to the Node B 110 and receives electromagnetic signals from the Node B 110 using the one or more antennas 106a-n. The Node B 110 communicates with the UE 102 using one or more antennas 108a-n. It should be noted that the Node B 110 may be an evolved Node B (eNB) or other kind of base station in some configurations.

The UE 102 and the Node B 110 may use multiple channels to communicate with each other. In the configuration illustrated in FIG. 1, a UE 102 may use a Physical Uplink Control Channel (PUCCH) 114 to send a joint SRI and ACK/NACK message 116 to the Node B 110. The PUCCH 114 is one example of a control channel pursuant to 3GPP specifications. For instance, the PUCCH 114 may be a DFT-spread OFDM (e.g., “Format 3”) PUCCH in some configurations. Other kinds of uplink channels 118 may be used. The Node B 110 may use one or more downlink channels 120 to send information to the UE 102. One example of a downlink channel 120 is a Physical Downlink Control Channel (PDCCH) pursuant to 3GPP specifications.

The UE 102 may include a transceiver 117, a decoder 127, an encoder 131 and an operations module 133. The transceiver 117 may include a receiver 119 and a transmitter 123. The receiver 119 may receive signals from the Node B 110 using one or more antennas 106a-n. For example, the receiver 119 may receive and demodulate received signals using a demodulator 121. The transmitter 123 may transmit signals to the Node B 110 using one or more antennas 106a-n. For example, the transmitter 123 may modulate signals using a modulator 125 and transmit the modulated signals.

The receiver 119 may provide a demodulated signal to the decoder 127. The UE 102 may use the decoder 127 to decode signals. The decoder 127 may include an ACK/NACK determination module 129. The ACK/NACK determination module 129 may determine whether data was received correctly. For example, the ACK/NACK determination module 129 may determine whether a packet was correctly or erroneously received. For instance, the ACK/NACK determination module 129 may generate an Acknowledgement or “ACK” represented by a ‘0’ bit for each correctly received packet and a Negative Acknowledgement or “NACK” represented by a ‘1’ bit for each incorrectly received packet. Alternatively, an “ACK” may be represented with a ‘1’ bit and a “NACK” may be represented by a ‘0’ bit. Thus, the decoder 127 may generate ACK/NACKs A 124a, which are provided to the encoder 131.

The operations module 133 may be a software and/or hardware module used to control UE 102 communications. For example, the operations module 133 may determine when the UE 102 requires resources to communicate with the Node B 110. For example, the SRI determination module 135 (included in the operations module 133) may determine that the UE 102 needs communication resources to download data or make a phone call. The SRI determination module 135 may generate Scheduling Request Indicator (SRI) A 122a when the UE 102 needs communication resources. For example, the SRI determination module 135 may generate a ‘1’ bit when communication resources are needed to communicate with the Node B 110 and a ‘0’ bit when communication resources are not needed to communicate with the Node B 110.

The encoder 131 may include a joint SRI and ACK/NACK encoding module 104. The joint SRI and ACK/NACK encoding module 104 may be implemented in hardware, software or a combination of both. As described above, the UE 102 may generate SRI A 122a (e.g., an SRI bit). An SRI (e.g., a “positive” SRI or SRI=1) indicates that the UE 102 is requesting or may request communication resources from the Node B 110. For example, the UE 102 may generate a positive SRI A 122a when communication resources on uplink channels 118 are needed to transmit information to the Node B 110. SRI A 122a may be represented as a single bit. For example, an SRI bit=0 may indicate that there is no current Scheduling Request (SR) or that no communication resources are requested by the UE 102. Conversely, an SRI bit=1 may indicate that there is a current SR or that communication resources are being requested by the UE 102.

As described above, the UE 102 may also generate one or more ACK/NACKs A 124a (e.g., ACK/NACK bits). ACK/NACKs A 124a may be generated based on correctly or incorrectly received information from the Node B 110. For example, the UE 102 may receive one or more packets from the Node B 110 using one or more downlink channels 120. The UE 102 may detect when a packet (e.g., data or a segment of information) is not correctly received. For example, the UE 102 may generate an Acknowledgment (ACK) for each packet that was correctly received and a Negative Acknowledgment (NACK) for each packet that was incorrectly received (or not received, for example). For instance, the UE 102 may represent each ACK/NACK with a bit, where a value of 1 represents a correctly received packet (e.g., an ACK) and a value of 0 represents an incorrectly received packet (e.g., a NACK).

The joint SRI and ACK/NACK encoding module 104 may produce a joint SRI and ACK/NACK message 116 using SRI A 122a and ACK/NACKs A 124a generated by the UE 102. The joint SRI and ACK/NACK encoding module 104 may provide unequal error protection between the SRI and ACK/NACKs. For example, the joint SRI and ACK/NACK encoding module 104 may encode an SRI such that it may be more or less reliably received than an ACK/NACK. For instance, the joint SRI and ACK/NACK encoding module 104 may provide greater or lesser redundancy for the SRI (e.g., more or fewer bits) than for each ACK/NACK. This may allow the Node B 110 to more or less reliably receive and decode the SRI than each ACK/NACK. This may provide the benefit that the SRI information is more reliably received by a Node B, thus allowing the Node B to schedule or prepare to schedule resources for the UE. Alternatively, this may provide the benefit that the ACK/NACK is more reliably received by the Node B than the SRI. This may be done if the Node B requires more reliable detection of ACK/NACK bits compared to SRI bits. It should be noted that the SRI and ACK/NACK message 116 may include both SRI and ACK/NACK information (within a group of bits, for example).

In one configuration, the joint SRI and ACK/NACK encoding module 104 may produce a joint SRI and ACK/NACK message 116 by adding repetition encoding to an SRI and encoding both the SRI and ACK/NACK bits using a Reed-Muller encoder. In another configuration, the joint SRI and ACK/NACK encoding module 104 may produce a joint SRI and ACK/NACK message 116 by adding repetition or Reed-Muller encoding to an SRI, encoding the ACK/NACK bits using a Reed-Muller encoder and then combining one or more of the encoded SRI bits with the encoded ACK/NACK bits.

In another configuration, the joint SRI and ACK/NACK encoding module 104 may produce a joint SRI and ACK/NACK message 116 by placing one or more encoded SRI bits in place of repeated ACK/NACK parity bits. For example, ACK/NACK bits may be encoded by a (higher-order) Reed-Muller encoder to produce encoded ACK/NACK bits with repeated parity bits. None, some or all of the repeated parity bits may be replaced by SRI bits. Or, the Reed-Muller encoder may avoid producing some or all of the repeated ACK/NACK parity bits, in which case one or more of the SRI bits may be placed in place of one or more non-generated ACK/NACK repeated parity bits.

In yet another configuration, the joint SRI and ACK/NACK encoding module 104 may produce a joint SRI and ACK/NACK message 116 by implicitly encoding an SRI into an encoded ACK/NACK message. For example, a sequence of ACK/NACK bits may be encoded by a Reed-Muller encoder to produce encoded ACK/NACK bits with repeated parity bits. If there is an SR (e.g., SRI=1), then one or more of the repeated parity bits may be flipped or inverted. If there is no SR (e.g., SRI=0), then the repeated parity bits may not be modified.

The joint SRI and ACK/NACK encoding module 104 may provide the joint SRI and ACK/NACK message 116 to the transmitter 123. The transmitter 123 may modulate the joint SRI and ACK/NACK message 116 using the modulator 125 and transmit it 116 on the PUCCH 114.

It should be noted that the PUCCH 114 may have limited communication resources or limited resources allocated to the UE 102 for SRIs and ACK/NACKs. Thus, the systems and methods herein may provide a benefit by providing efficient ways to jointly encode an SRI and ACK/NACKs into a joint SRI and ACK/NACK message 116 when simultaneous transmission of an SRI and ACK/NACKs is desired or needed.

The Node B 110 may include a transceiver 107, comprising a receiver 109 and a transmitter 113. The Node B 110 may additionally include a decoder 103, an encoder 105 and an operations module 194. The Node B 110 may receive the joint SRI and ACK/NACK message 116 using its one or more antennas 108a-n and its receiver 109. The receiver 109 may use the demodulator 111 to demodulate the joint SRI and ACK/NACK message 116.

The decoder 103 may include a joint SRI and ACK/NACK decoding module 112. The Node B 110 may use the joint SRI and ACK/NACK decoding module 112 to decode and/or interpret the joint SRI and ACK/NACK message 116 received by the Node B 110. The Node B 110 may use the decoded joint SRI and ACK/NACK message 116 to perform certain operations, such as retransmit one or more packets based on the ACK/NACKs and/or schedule or prepare to schedule communication resources for the UE 102 based on the SRI.

For example, the joint SRI and ACK/NACK decoding module 112 may decode the joint SRI and ACK/NACK message 116 to produce ACK/NACKs B 124b and SRI B 122b (from the joint SRI and ACK/NACK message 116, for example). ACK/NACKs B 124b and SRI B 122b may be provided to the operations module 194. The operations module 194 may include a retransmission module 196 and a scheduling module 198. The retransmission module 196 may determine which packets to retransmit (if any) based on ACK/NACKs B 124b. The scheduling module 198 may be used by the Node B 110 to schedule communication resources (e.g., bandwidth, time slots, frequency channels, spatial channels, etc.). The scheduling module 198 may use SRI B 122b to determine whether (and when) to schedule communication resources for the UE 102.

The operations module 194 may provide data 101 to the encoder 105. For example, the data 101 may include packets for retransmission and/or a scheduling grant for the UE 102. The encoder 105 may encode the data 101, which may then be provided to the transmitter 113. The transmitter 113 may modulate the encoded data using the modulator 115. The transmitter 113 may transmit the modulated data to the UE 102 using one or more antennas 108a-n.

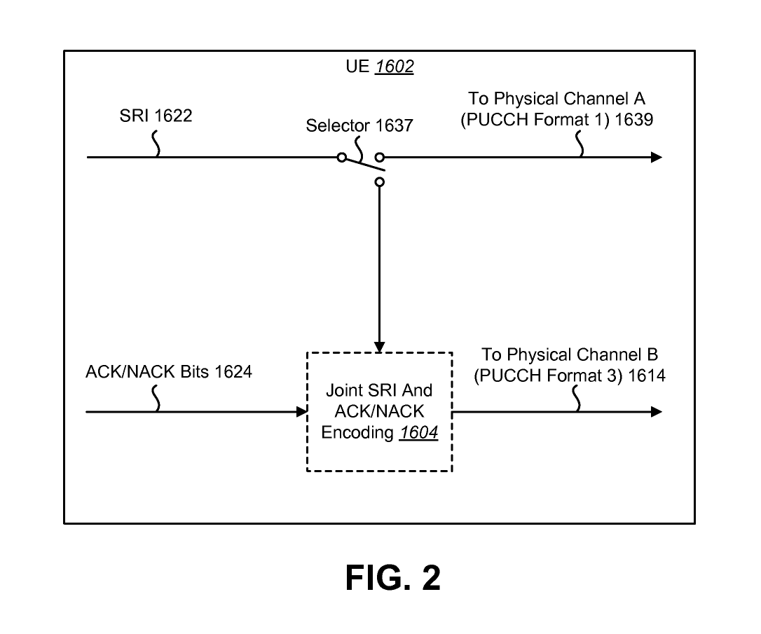

FIG. 2 is a block diagram illustrating another configuration of a User Equipment (UE) 1602 in which systems and methods for jointly encoding a Scheduling Request Indicator (SRI) and Acknowledgments/Negative Acknowledgments (ACK/NACKs) may be implemented. In particular, FIG. 2 illustrates that a joint SRI and ACK/NACK encoding module 1604 may be used when an SRI 1622 and ACK/NACK bits 1624 are to be transmitted simultaneously. For example, the UE 1602 may include a selector 1637. The selector 1637 may be used to switch between physical channel A (with PUCCH Format 1) 1639 and physical channel B (with PUCCH Format 3) 1614.

When an SRI 1622 and ACK/NACK bits 1624 do not need to be transmitted simultaneously, the UE 1602 (using the selector 1637, for example) may utilize physical channel A (with PUCCH Format 1) 1639. This may occur when the SRI 1622 and ACK/NACK bits 1624 are not generated at the same time or otherwise do not need to be transmitted at the same time. However, when an SRI 1622 and a large ACK/NACK (as in Release-10) are generated at the same time or need to be transmitted simultaneously, the UE 1602 (using the selector 1637, for example) may use the joint SRI and ACK/NACK encoding module 1604 to jointly encode the SRI 1622 and ACK/NACK bits 1624 for transmission using physical channel B (with PUCCH format 3) 1614. It should be noted that in LTE, 1 or 2 bits of ACK/NACK could be simultaneously transmitted using the Scheduling Request (SR) resource when there is an SR present using Format 1A or Format 1B. However, for a larger size ACK/NACK as in Release-10, joint encoding of the SRI 1622 and ACK/NACK bits 1624 may be needed.

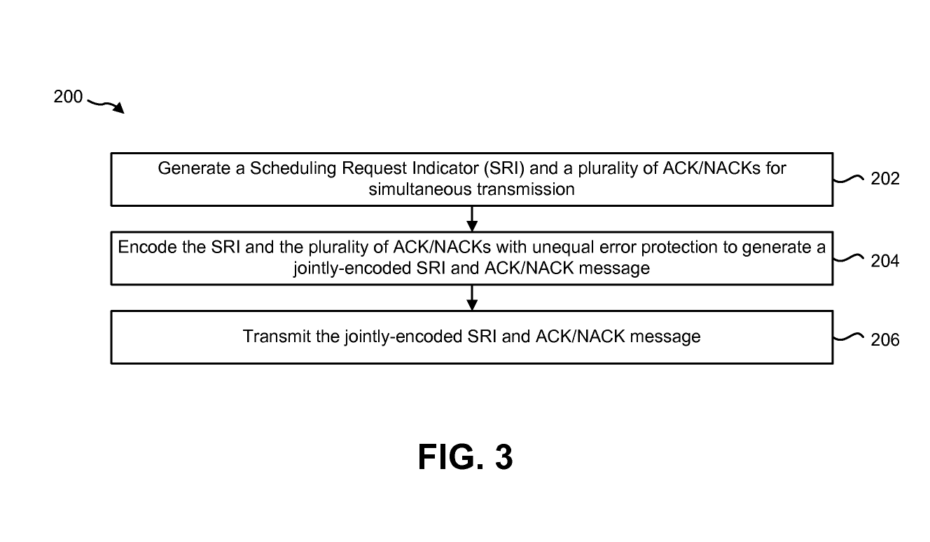

FIG. 3 is a flow diagram illustrating one configuration of a method 200 for jointly encoding a Scheduling Request Indicator (SRI) and Acknowledgments/Negative Acknowledgments (ACK/NACKs). A UE 102 may generate 202 an SRI (e.g., SRI bit) and a plurality of ACK/NACKs (e.g., ACK/NACK bits) for simultaneous transmission. For example, the UE 102 may generate 202 an SRI bit based on whether the UE 102 is or will be requesting communication resources from a Node B 110. Furthermore, the UE 102 may also generate 202 a plurality of ACK/NACK bits based on whether data or segments of data (e.g., packets) were correctly or incorrectly received. This method 200 may be used when the SRI and ACK/NACKs are generated for simultaneous transmission (e.g., when both an SRI and ACK/NACKs are generated at the same time or need to be transmitted to a Node B 110 at the same time).

The UE 102 may encode 204 the SRI and the plurality of ACK/NACKs with unequal error protection to generate a jointly-encoded SRI and ACK/NACK message. For example, the UE 102 encodes 204 the SRI and the plurality of ACK/NACKs such that the SRI may be more or less reliably received than each ACK/NACK. Unequal error protection may be provided by using more redundancy or more bits of information for the SRI (e.g., to represent the SRI) than for each ACK/NACK (e.g., to represent each ACK/NACK). Alternatively, less redundancy or fewer bits of information may be provided to the SRI and more bits of protection to the ACK/NACK. This may provide the benefit that the SRI information is more reliably received by a Node B 110, thus allowing the Node B 110 to schedule or prepare to schedule resources for the UE 102. Alternatively, this may provide the benefit that the ACK/NACK information is more reliably received by the Node B, thus allowing for better detection of the ACK/NACK. Encoding 204 may involve, for example, repetition encoding and/or Reed-Muller encoding. This may be implemented in many ways. More specific implementations are described below.

The UE 102 may transmit 206 the jointly-encoded SRI and ACK/NACK message 116. For example, the UE 102 may transmit the jointly-encoded message 116 using one or more antennas 106a-n on a PUCCH 114. The Node B 110 may receive the jointly-encoded SRI and ACK/NACK message 116 using one or more antennas 108a-n.

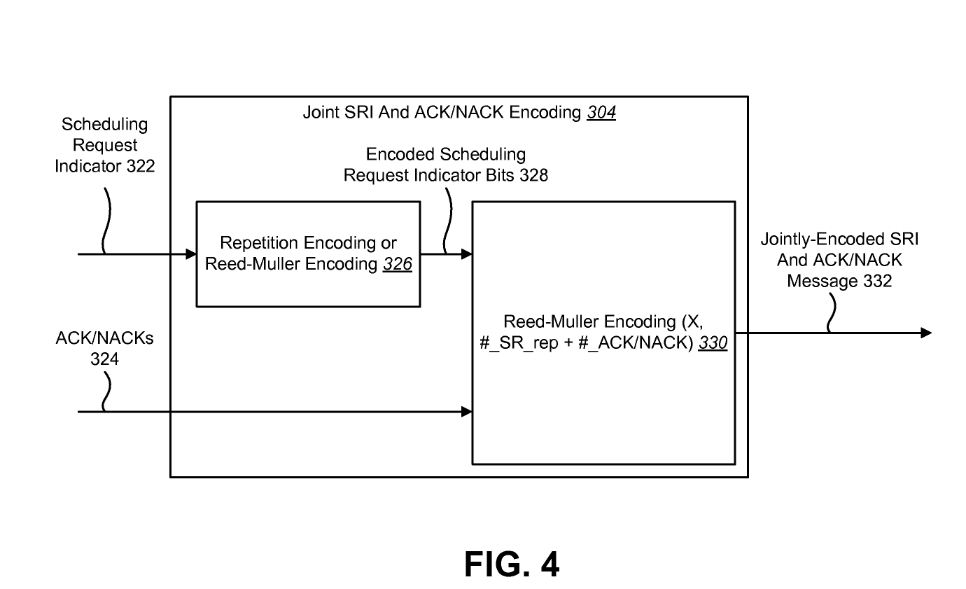

FIG. 4 is a block diagram illustrating one configuration of a joint Scheduling Request Indicator (SRI) and Acknowledgment/Negative Acknowledgment (ACK/NACK) encoding module 304. More specifically, FIG. 4 illustrates one implementation of the systems and methods disclosed herein. In the configuration illustrated in FIG. 4, the joint SRI and ACK/NACK encoding module 304 may include a repetition encoding or Reed-Muller encoding module 326 and a Reed-Muller encoding module 330.

The joint SRI and ACK/NACK encoding module 304 may receive or obtain a Scheduling Request Indicator (SRI) 322. For example, the UE 102 may generate the SRI 322. The input SRI 322 may be represented using a single bit. For example, an SRI of 1 may indicate a scheduling request, while an SRI of 0 may indicate that there is no scheduling request.

The SRI 322 may be input into the repetition encoding or Reed-Muller encoding module 326. The repetition encoding or Reed-Muller encoding module 326 may encode an SRI 322 (bit) by repeating the SRI bit a given number of times or by encoding the SRI bit using Reed-Muller encoding to produce a number (e.g., 0, 1 or more) of encoded scheduling request indicator (SRI) bits 328. For example, if the SRI bit is 1, the repetition encoding or Reed-Muller encoding module 326 may repeat it to produce a sequence of 16 (or fewer) bits: 1111111111111111 or may encode it into a Reed-Muller encoded sequence. For example, zero or more bits may be used to represent the SRI bit, depending on the amount of error protection desired and whether SRI or ACK/NACK information should receive greater error protection. This may provide the benefit that the amount of error protection may be flexibly configured depending, for example, on system performance, system configuration and/or channel conditions. It should be noted that in one configuration, the SRI 322 bit may not be repeated. Thus, for example, the repetition encoding module 326 may “encode” the SRI bit by not repeating it.

The joint SRI and ACK/NACK encoding module 304 may receive or obtain one or more ACK/NACKs 324. The ACK/NACKs 324 may be a series of indicators, where each ACK/NACK indicates whether corresponding data (e.g., a packet, segment of data, group of bits, etc.) was successfully received. For example, each ACK/NACK may be represented as a bit, where a value of 1 indicates a successful data reception and a value of 0 represents an unsuccessful data reception.

The encoded scheduling request indicator bits 328 and the ACK/NACKs 324 may be input into the Reed-Muller encoding module 330. In the configuration illustrated in FIG. 4, the Reed-Muller encoding module 330 encodes both the encoded scheduling request indicator bits 328 and the ACK/NACKs 324 to produce a jointly-encoded SRI and ACK/NACK message 332. In this case, the Reed-Muller encoding module 330 may encode based on three parameters: X, “#_SR_rep” and “#_ACK/NACK.” The X parameter represents the number of bits from the Reed-Muller encoder. #_SR_rep is the number of encoded scheduling request indicator bits and the “#_ACK/NACK” parameter is the number of ACK/NACKs 324 to be jointly encoded. More specifically, the Reed-Muller encoding module 330 may encode based on X and the sum of #_SR_rep and #_ACK/NACK. The Reed-Muller encoding module 330 may provide or output the jointly-encoded SRI and ACK/NACK message 332. It should be noted that the encoded SRI bits 328 may include zero, one or more encoded SRI bits 328 depending on the amount of error protection allocated to the SRI 322 versus the ACK/NACKs 324 (e.g., whether greater error protection is used for the SRI 322 or the ACK/NACKs 324 and to what extent).

Optionally, the joint SRI and ACK/NACK encoding module 304 may include an interleaver. For example, the encoded scheduling request indicator bits 328 may be interleaved with the ACK/NACK bits 324. This may provide a benefit of greater tolerance against fading and/or protection against burst errors.

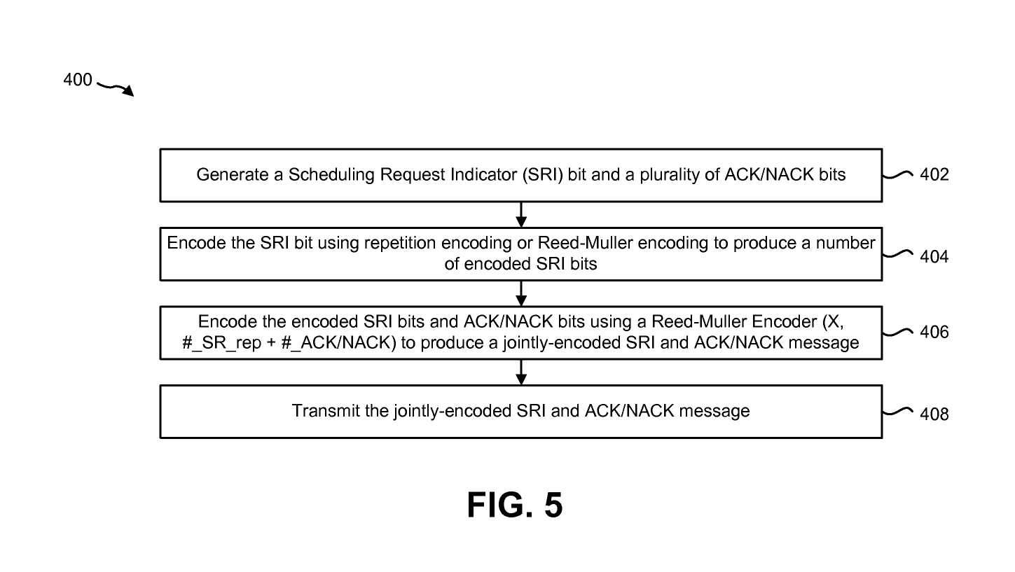

FIG. 5 is a flow diagram illustrating a more specific configuration of a method 400 for jointly encoding a Scheduling Request Indicator (SRI) and Acknowledgments/Negative Acknowledgments (ACK/NACKs). A UE 102 may generate 402 an SRI bit 322 and a plurality of ACK/NACK bits 324 as described above. The UE 102 (e.g., joint SRI and ACK/NACK encoding module 304) may optionally encode 404 the SRI bit 322 using repetition encoding and/or Reed-Muller encoding to produce zero, one or more encoded SRI bits 328. For example, the UE 102 may or may not repeat the SRI bit 322 in order to produce a given number of encoded SRI bits 328.

The UE 102 may encode 406 the encoded SRI bits 328 and ACK/NACK bits 324 using a Reed-Muller encoder (using parameters X, #_SR_rep and #_ACK/NACK as described above, for example) to produce a jointly-encoded SRI and ACK/NACK message 332. Encoding the SRI bit 322 and ACK/NACK bits 324 in this way may provide unequal error protection by providing greater or lesser reliability (e.g., greater or lesser redundancy) to the SRI than to each ACK/NACK. This may provide the benefit that the SRI information is more reliably received by a Node B 110, thus allowing the Node B 110 to schedule or prepare to schedule resources for the UE 102. Alternatively, this may provide the benefit that the ACK/NACK information is more reliably received by a Node B 110, allowing more reliable detection of ACK/NACK information. The UE 102 may transmit 408 the jointly-encoded SRI and ACK/NACK message 332. For example, the UE 102 may transmit 408 the joint message 332 on a PUCCH 114 using one or more antennas 106a-n.

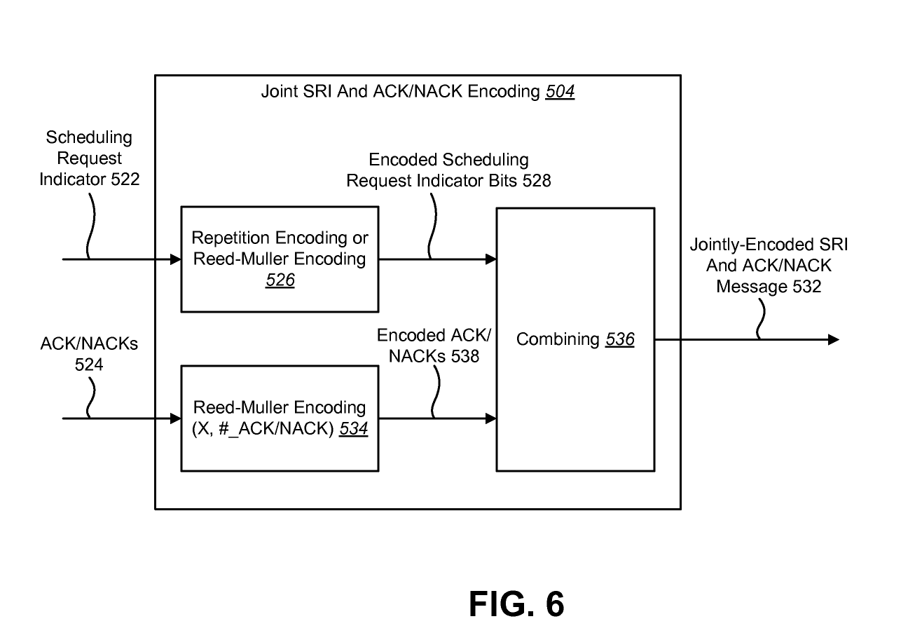

FIG. 6 is a block diagram illustrating another configuration of a joint Scheduling Request Indicator (SRI) and Acknowledgment/Negative Acknowledgment (ACK/NACK) encoding module 504. More specifically, FIG. 6 illustrates one implementation of the systems and methods disclosed herein. In the configuration illustrated in FIG. 6, the joint SRI and ACK/NACK encoding module 504 may include a repetition encoding or Reed-Muller encoding module 526, a Reed-Muller encoding module 534 and a combining module 536.

The joint SRI and ACK/NACK encoding module 504 may receive or obtain a Scheduling Request Indicator (SRI) 522. For example, the UE 102 may generate the SRI 522. The input SRI 522 may be represented using a single bit. For example, an SRI of 1 may indicate a scheduling request, while an SRI of 0 may indicate that there is no scheduling request.

The SRI 522 may be input into the repetition encoding or Reed-Muller encoding module 526. The repetition encoding or Reed-Muller encoding module 526 may encode an SRI 522 (bit) by repeating the SRI bit a given number of times or by encoding the SRI bit using Reed-Muller encoding to produce a number (e.g., 0, 1 or more) of encoded scheduling request indicator (SRI) bits 528. For example, if the SRI bit is 1, the repetition encoding or Reed-Muller encoding module 526 may repeat it to produce a sequence of 16 bits: 1111111111111111 or may encode it into a Reed-Muller encoded sequence. For example, zero or more bits may be used to represent the SRI bit, depending on the amount of error protection desired and whether SRI or ACK/NACK information should receive greater error protection.

The joint SRI and ACK/NACK encoding module 504 may receive or obtain one or more ACK/NACKs 524 (generated by the UE 102, for example). The ACK/NACKs 524 may be a series of indicators, where each ACK/NACK indicates whether corresponding data (e.g., a packet, segment of data, group of bits, etc.) was successfully received. For example, each ACK/NACK may be represented as a bit, where a value of 1 indicates a successful data reception and a value of 0 represents an unsuccessful data reception.

The ACK/NACKs 524 may be input into the Reed-Muller encoding module 534. In the configuration illustrated in FIG. 6, the Reed-Muller encoding module 534 encodes the ACK/NACKs 524 to produce encoded ACK/NACKs (e.g., encoded ACK/NACK bits) 538. In this case, the Reed-Muller encoding module 534 may encode based on two parameters: X and “# ACK/NACK.” The X parameter represents the order of the number of bits from the Reed-Muller encoder. The “# ACK/NACK” parameter is the number of ACK/NACKs 524 to be encoded.

The encoded SRI bits 528 and the encoded ACK/NACK bits 538 may be combined by the combining module 536. For example, the combining module 536 may combine zero, one or more of the encoded SRI bits 528 with (or append the encoded SRI bits 528 to) the encoded ACK/NACK bits 538 to produce a jointly-encoded SRI and ACK/NACK message 532. That is, the combining module 536 may provide or output the jointly-encoded SRI and ACK/NACK message 532, for example.

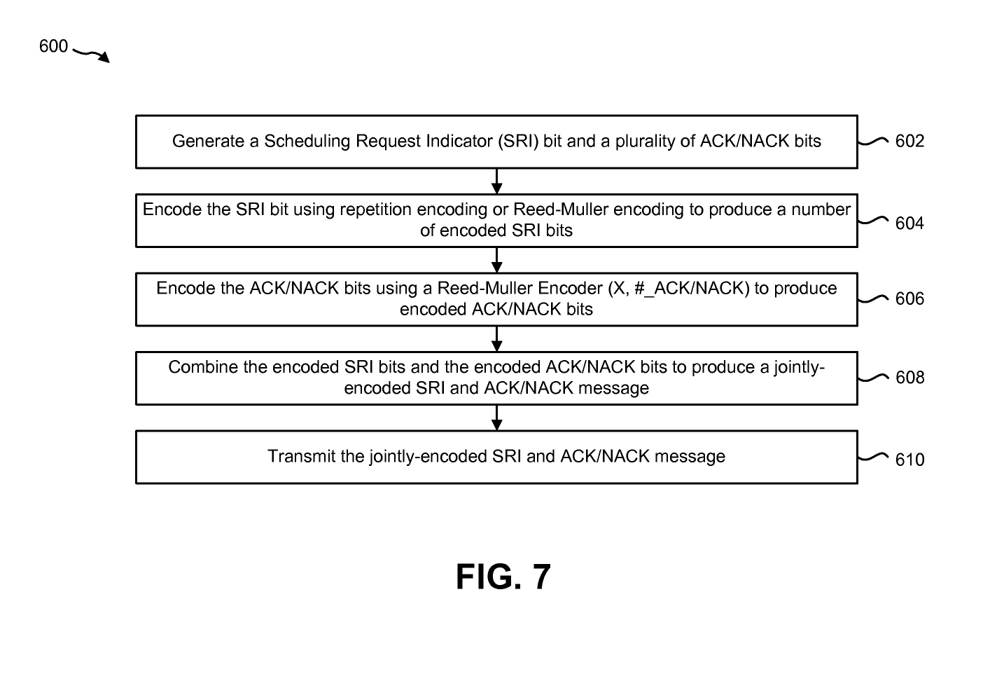

FIG. 7 is a flow diagram illustrating another more specific configuration of a method 600 for jointly encoding a Scheduling Request Indicator (SRI) and Acknowledgments/Negative Acknowledgments (ACK/NACKs). A UE 102 may generate 602 an SRI bit 522 and a plurality of ACK/NACK bits 524 as described above. The UE 102 (e.g., joint SRI and ACK/NACK encoding module 504) may encode 604 the SRI bit using repetition encoding or Reed-Muller encoding to produce zero, one or more encoded SRI bits 528. For example, the UE 102 may repeat the SRI bit 522 in order to produce a given number of encoded SRI bits 528.

The UE 102 may encode 606 the ACK/NACK bits 524 using a Reed-Muller encoder (using parameters X and #_ACK/NACK as described above, for example) to produce encoded ACK/NACK bits 538. The UE 102 may combine 608 zero, one or more of the encoded SRI bits 528 and the encoded ACK/NACK bits 538 to produce a jointly-encoded SRI and ACK/NACK message 532. The encoded SRI bits 528 and the encoded ACK/NACK bits 538 may be combined by appending the encoded SRI bits 528 to the ACK/NACK bits 538, for example. Encoding the SRI bit 522 and ACK/NACK bits 524 in this way may provide unequal error protection by providing greater or lesser reliability (e.g., greater or lesser redundancy) to the SRI than to each ACK/NACK. This may provide the benefit that the SRI information is more reliably received by a Node B 110, thus allowing the Node B 110 to schedule or prepare to schedule resources for the UE 102. The UE 102 may transmit 610 the jointly-encoded SRI and ACK/NACK message 532. For example, the UE 102 may transmit 610 the joint message 532 on a PUCCH 114 using one or more antennas 106a-n. Alternatively, if more bits are allocated to ACK/NACK encoding compared to SRI, more reliability is provided to ACK/NACK transmission compared to SRI. This may provide the benefit that a Node B may more reliably detect the ACK/NACK, thus causing fewer retransmissions of false detections of NACK.

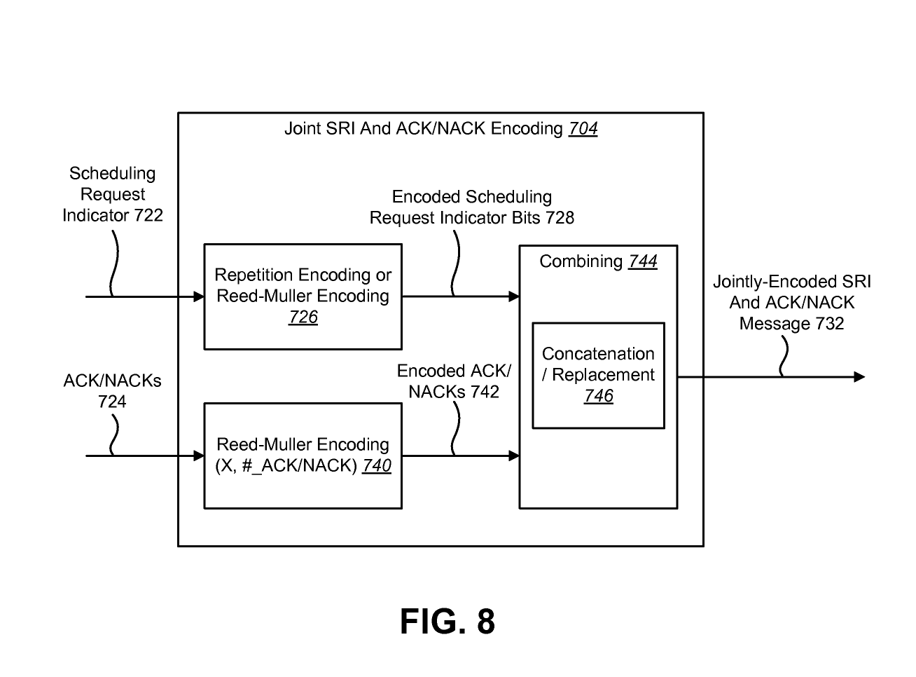

FIG. 8 is a block diagram illustrating another configuration of a joint Scheduling Request Indicator (SRI) and Acknowledgment/Negative Acknowledgment (ACK/NACK) encoding module 704. More specifically, FIG. 8 illustrates one implementation of the systems and methods disclosed herein. In the configuration illustrated in FIG. 8, the joint SRI and ACK/NACK encoding module 704 may include a repetition encoding or Reed-Muller encoding module 726, a Reed-Muller encoding module 740 and a combining module 744.

The joint SRI and ACK/NACK encoding module 704 may receive or obtain a Scheduling Request Indicator (SRI) 722. For example, the UE 102 may generate the SRI 722. The input SRI 722 may be represented using a single bit. For example, an SRI of 1 may indicate a scheduling request, while an SRI of 0 may indicate that there is no scheduling request.

The SRI 722 may be input into the repetition encoding or Reed-Muller encoding module 726. The repetition encoding or Reed-Muller encoding module 726 may encode an SRI 722 (bit) by repeating the SRI bit a given number of times or by encoding the SRI bit using Reed-Muller encoding to produce a number (e.g., 0, 1 or more) encoded scheduling request indicator (SRI) bits 728. For example, if the SRI bit is 1, the repetition encoding or Reed-Muller encoding module 726 may repeat it to produce a sequence of 16 bits: 1111111111111111 or may encode it into a Reed-Muller encoded sequence. For example, zero or more bits may be used to represent the SRI bit, depending on the amount of error protection desired and whether SRI or ACK/NACK information should receive greater error protection.

The joint SRI and ACK/NACK encoding module 704 may receive or obtain one or more ACK/NACKs 724 (generated by the UE 102, for example). The ACK/NACKs 724 may be a series of indicators, where each ACK/NACK indicates whether corresponding data (e.g., a packet, segment of data, group of bits, etc.) was successfully received. For example, each ACK/NACK may be represented as a bit, where a value of 1 indicates a successful data reception and a value of 0 represents an unsuccessful data reception.

The ACK/NACKs 724 may be input into the Reed-Muller encoding module 740. In the configuration illustrated in FIG. 8, the Reed-Muller encoding module 740 encodes the ACK/NACKs 724 to produce encoded ACK/NACKs (e.g., encoded ACK/NACK bits) 742. In this case, the Reed-Muller encoding module 740 may encode based on two parameters: X and “# ACK/NACK.” The X parameter represents the number of bits from the Reed-Muller encoder. The “# ACK/NACK” parameter is the number of ACK/NACKs 724 to be encoded.

The Reed-Muller encoding module 740 may use “higher-order” Reed-Muller encoding. For example, the Reed-Muller encoding module 740 may produce (e.g., may typically produce) a number of repeated parity bits using circular repetition. In one configuration, the combining module 744 may use a replacement function 746 to replace a number of the repeated parity bits with zero, one or more of the encoded SRI bits 728. In other words, none, some or all of the repeated parity bits may be discarded and replaced by the encoded SRI bits 728. In another configuration, the Reed-Muller encoding module 740 may avoid generating a number of the repeated parity bits (that otherwise would have been generated). In this case, the combining module 744 may use a concatenation function 746 to concatenate, insert or append the zero, one or more encoded SRI bits 728 in place of the repeated parity bits that were not generated. In other words, none, some or all of the non-generated repeated parity bits (depending on the level of protection required for SRI compared to ACK/NACK) may be replaced by a corresponding number of encoded SRI bits 728.

Thus, the encoded SRI bits 728 and the encoded ACK/NACK bits 742 may be combined by the combining module 744. For example, the jointly-encoded SRI and ACK/NACK message may comprise encoded ACK/NACK bits 742 with zero, one or more repeated parity bits that are replaced by the encoded SRI bits 728. That is, the combining module 744 may provide or output the jointly-encoded SRI and ACK/NACK message 732, for example.

More specifically, this approach may involve joint encoding for higher-order Reed-Muller encoding with a repetition of SRI bits. For example, a (32, O) Reed-Muller encoding may be extended to 48 encoded bits using circular buffer matching. Instead of using a circular buffer, however, the ACK/NACK may be transmitted using the (32, O) Reed-Muller encoding and the SRI using the other 16 encoded bits (or any ‘N’ number of bits where 0≦N≦16) by using another encoding. For instance, the SRI 722 may be encoded using repetition encoding 726 and/or another Reed-Muller encoding (e.g., the repetition encoding module 726 may be replaced by another Reed-Muller encoding module in some configurations).

In this case, instead of using circular repetition of the encoded HARQ-ACK (and SR) bits, zero, one or more of the encoded bits are used to represent SRI information. For instance, the input bits may be up to 10 ACK/NACK only bits which is encoded to 32 bits as described above. However, none, part or all of the circular repetition may be used for SRI representation. If the entire circular repetition is used for SR, for example, the 16 bits can be an all-1 sequence or an all-0 sequence depending on positive or negative SR, respectively.

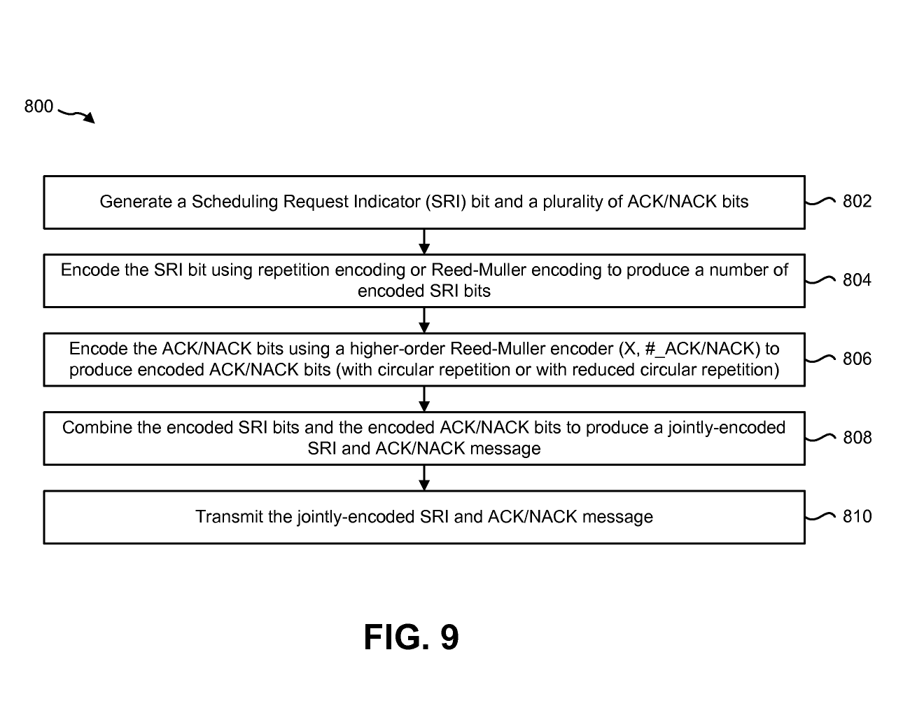

FIG. 9 is a flow diagram illustrating another more specific configuration of a method 800 for jointly encoding a Scheduling Request Indicator (SRI) and Acknowledgments/Negative Acknowledgments (ACK/NACKs). A UE 102 may generate 802 an SRI bit 722 and a plurality of ACK/NACK bits 724 as described above. The UE 102 (e.g., joint SRI and ACK/NACK encoding module 704) may optionally encode 804 the SRI bit using repetition encoding or Reed-Muller encoding to produce zero, one or more encoded SRI bits 728. For example, the UE 102 may repeat the SRI bit 722 in order to produce a given number of encoded SRI bits 728. In an alternative configuration, separate Reed-Muller encoding may be used to generate encoded SRI bits that may be used according to the systems and methods disclosed herein.

The UE 102 may encode 806 the ACK/NACK bits 724 using a higher-order Reed-Muller encoder (using parameters X and “#_ACK/NACK” as described above, for example) to produce encoded ACK/NACK bits 742. As described above, the Reed-Muller encoder may use circular repetition to generate repeated parity bits in one configuration. None, some or all of these repeated parity bits may be replaced by SRI bits as described hereafter. In another configuration, the Reed-Muller encoder may use reduced circular repetition to avoid generating some or all of the repeated parity bits for the SRI bits as described hereafter.

The UE 102 may combine 808 the zero, one or more encoded SRI bits 728 and the encoded ACK/NACK bits 742 by replacing none, some or all of the repeated parity bits with encoded SRI bits 728. Alternatively, the UE 102 may combine 808 them 742, 728 by not generating some or all of the repeated parity bits in order to place encoded SRI bits 728 in their place. In other words, zero, one or more of the repeated parity bits generated using circular repetition may be replaced by encoded SRI bits 728 or reduced circular repetition may be used in order to “make room” for encoded SRI bits 728. Combining 808 the encoded SRI bits 728 and the encoded ACK/NACK bits 742 may produce a jointly-encoded SRI and ACK/NACK message 732. Encoding the SRI bit 722 and ACK/NACK bits 724 in this way may provide unequal error protection by providing greater or lesser reliability (e.g., greater or lesser redundancy) to the SRI than to each ACK/NACK. This may provide the benefit that the SRI information is more reliably received by a Node B 110, thus allowing the Node B 110 to schedule or prepare to schedule resources for the UE 102. Alternatively, this may provide the benefit that the ACK/NACK is more reliably received (and the SRI less reliably received) by the Node B, allowing more reliable or accurate detection of ACK/NACK information.

The UE 102 may transmit 810 the jointly-encoded SRI and ACK/NACK message 732. For example, the UE 102 may transmit 810 the joint message 732 on a PUCCH 114 using one or more antennas 106a-n.

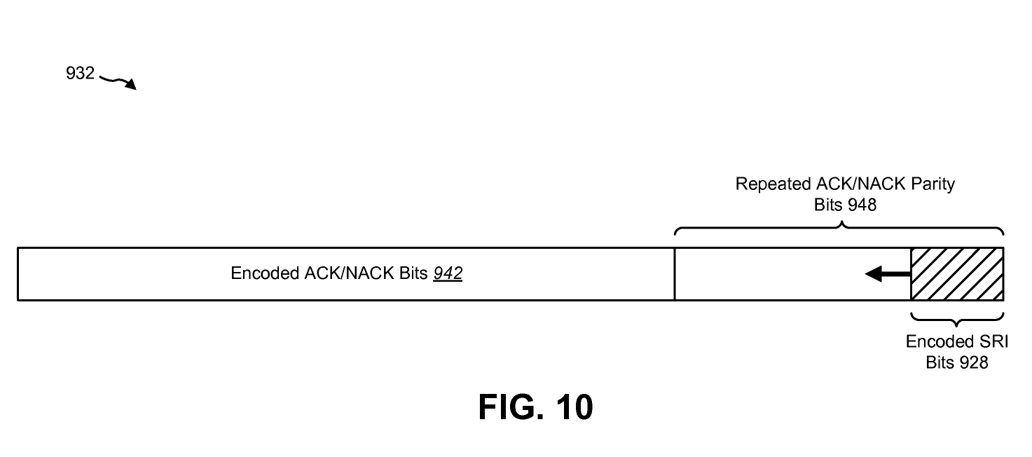

FIG. 10 is a diagram illustrating one example of a jointly-encoded Scheduling Request Indicator (SRI) and Acknowledgment/Negative Acknowledgment (ACK/NACK) message 932. More specifically, FIG. 10 illustrates one example of a jointly-encoded SRI and ACK/NACK message 932 that may be generated according to the method 800 illustrated in FIG. 9.

For example, a Reed-Muller encoding module 740 may generate the encoded ACK/NACK bits 942 using input ACK/NACKs 724. In some configurations, the Reed-Muller encoding module 740 may generate a number of repeated ACK/NACK parity bits 948. As described above, repetition encoding module 726 may generate zero, one or more encoded SRI bits 928 using an SRI 722. The combining module 744 may replace zero, one or more of the repeated ACK/NACK parity bits 948 with encoded SRI bits 928.

In another configuration, the Reed-Muller encoding module 740 may not generate some or all of the repeated ACK/NACK parity bits 948 in order to allow the SRI bits 928 to be appended or concatenated to the encoded ACK/NACK bits 942 (and/or to a number of repeated ACK/NACK parity bits 948, for example). Thus, the SRI bits 928 may occupy none, some or all of the bit locations typically used for the repeated ACK/NACK parity bits 948.

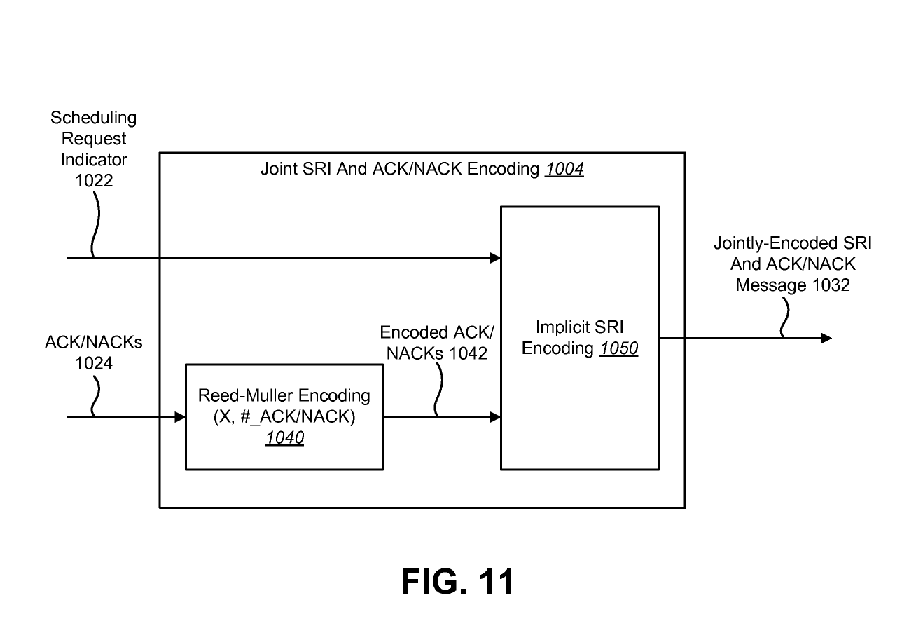

FIG. 11 is a block diagram illustrating another configuration of a joint Scheduling Request Indicator (SRI) and Acknowledgment/Negative Acknowledgment (ACK/NACK) encoding module 1004. More specifically, FIG. 11 illustrates one implementation of the systems and methods disclosed herein. In the configuration illustrated in FIG. 11, the joint SRI and ACK/NACK encoding module 1004 includes a Reed-Muller encoding module 1040 and an implicit SRI encoding module 1050.

The joint SRI and ACK/NACK encoding module 1004 may receive or obtain a Scheduling Request Indicator (SRI) 1022. For example, the UE 102 may generate the SRI 1022. The input SRI 1022 may be represented using a single bit. For example, an SRI of 1 may indicate a scheduling request, while an SRI of 0 may indicate that there is no scheduling request.

The joint SRI and ACK/NACK encoding module 1004 may receive or obtain one or more ACK/NACKs 1024. The ACK/NACKs 1024 may be a series of indicators, where each ACK/NACK indicates whether corresponding data (e.g., a packet, segment of data, group of bits, etc.) was successfully received. For example, each ACK/NACK may be represented as a bit, where a value of 1 indicates a successful data reception and a value of 0 represents an unsuccessful data reception.

The ACK/NACKs 1024 may be input into the Reed-Muller encoding module 1040. In the configuration illustrated in FIG. 11, the Reed-Muller encoding module 1040 encodes the ACK/NACKs 1024 to produce encoded ACK/NACKs (e.g., encoded ACK/NACK bits) 1042. In this case, the Reed-Muller encoding module 1040 may encode based on two parameters: X and “# ACK/NACK.” The X parameter represents the number of bits from the Reed-Muller encoder. The “# ACK/NACK” parameter is the number of ACK/NACKs 1024 to be encoded.

The Reed-Muller encoding module 1040 may use “higher-order” Reed-Muller encoding. For example, the Reed-Muller encoding module 1040 may produce a number of repeated parity bits using circular repetition. The implicit SRI encoding module 1050 may use zero, one or more of these repeated parity bits in order to implicitly encode or indicate the SRI 1022. For example, the implicit SRI encoding module 1050 may invert zero, one or more of the repeated parity bits depending on the SRI 1022. For instance, if the SRI is 1 (indicating a scheduling request, for example), the implicit SRI encoding module may invert or “flip” one or more of the repeated parity bits (e.g., each 0 is changed to 1 and each 1 is changed to 0). If the SRI is 0, the implicit SRI encoding module may not modify the repeated parity bits. Thus, the implicit SRI encoding module 1050 may produce the jointly-encoded SRI and ACK/NACK message 1032.

More specifically, this approach involves joint encoding using higher-order Reed-Muller encoding with inverted repeated parity bits. In this approach, the entirety or a lesser number of repeated parity bits (e.g., the 16 circular buffer bits, for example) are transmitted without modification when there is no SR and may be inverted or flipped (e.g., 0 becomes 1 and 1 becomes 0) when there is an SR transmission. In this way, the decoder can detect the SR transmission based on the joint detection of SR and ACK/NACK. The decoder may blindly decode under both hypotheses and decide on whether it was a positive SRI. Additionally, the 1 or more SR bits could also be transmitted jointly with the ACK/NACK and the 16 circular buffer bits transmitted as described above. Moreover, in other configurations, more than 16 circular buffer bits for the (32, O) Reed-Muller encoding (e.g., the last ‘N’ bits) could be transmitted without modification or be inverted or flipped as described above.

For instance, if there is no SR (e.g., SRI=0), the sequence or representation may be identical to the encoding of up to 10 bits of ACK/NACK information (similar to that described above). However, if there is a positive SR (e.g., SRI=1), the circular repetition bits (e.g., repeated parity bits) are inverted or flipped. That is, ‘0’ bits are changed to ‘1’ bits and ‘1’ bits are changed to ‘0’ bits for qᵢ, where i=33, . . . , 48. The decoder can first use the first 16 bits and the last 16 bits (or M bits, where M≦16, for example) from the demodulated data and determine whether it is a positive or negative SR. Then, depending on the decoded SR, the decoder may decode the 48 bit encoded data. For example, the last 16 (or M) bits may be inverted (on the decoding side) for decoding if a positive SR is determined. However, if a negative SR is determined, the decoder may decode the 48 bits of encoded data without modification.

Thus, zero, one or more of the encoded ACK/NACKs 1042 (e.g., repeated ACK/NACK parity bits) may be used to implicitly indicate an SRI 1022. The number of encoded ACK/NACKs 1042 (e.g., repeated ACK/NACK parity bits) used to indicated an SRI 1022 may depend on the amount of error protection allocated to the SRI information versus the ACK/NACK information. For example, more error protection may be allocated to SRI information by using more encoded ACK/NACK bits 1042 to indicate an SRI. On the other hand, less error protection may be allocated to SRI information by using fewer encoded ACK/NACK bits 1042 to indicate an SRI. One benefit of the approach illustrated in FIG. 11 may be that no bits are explicitly allocated to represent SRI. Thus, an SRI may be indicated without greatly reducing the error protection provided for ACK/NACK information. Nevertheless, greater or lesser error protection may be provided to the SRI information compared to the ACK/NACK information based on the number of encoded ACK/NACK bits 1042 used to represent the SRI information. For instance, if the number of ACK/NACK bits 1042 used to indicate an SRI is greater than the number of bits used to represent an ACK/NACK bit (e.g., the amount of redundancy), then the SRI may be afforded greater error protection than the ACK/NACK bit. Alternatively, if fewer ACK/NACK bits 1042 are used to indicate an SRI than are used to represent an ACK/NACK bit, then the SRI may be afforded less error protection than an ACK/NACK bit.

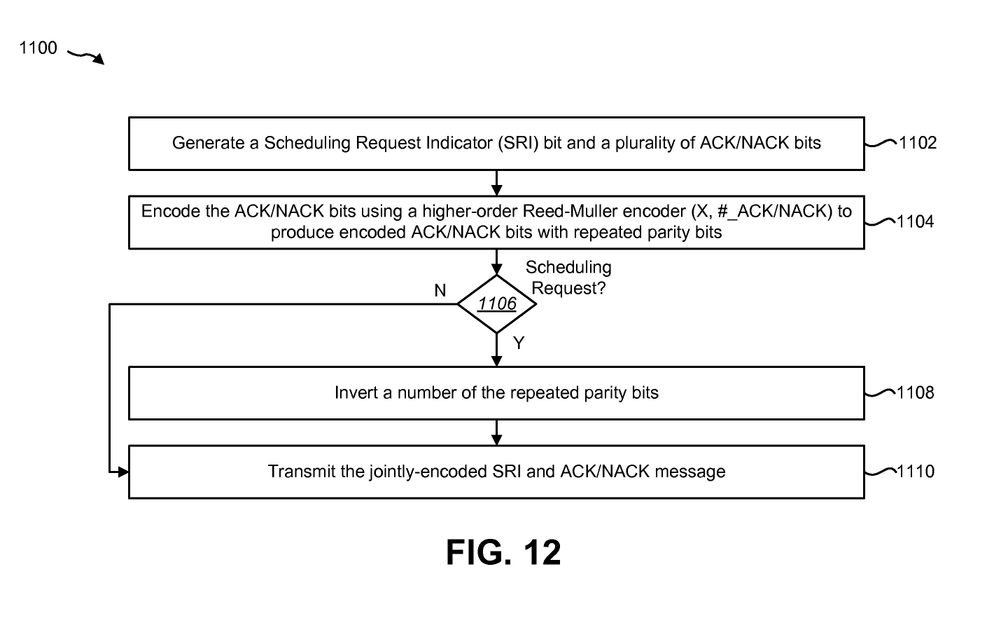

FIG. 12 is a flow diagram illustrating another more specific configuration of a method 1100 for jointly encoding a Scheduling Request Indicator (SRI) and Acknowledgments/Negative Acknowledgments (ACK/NACKs). A UE 102 may generate 1102 an SRI bit 1022 and a plurality of ACK/NACK bits 1024 as described above.

The UE 102 may encode 1104 the ACK/NACK bits 1024 using a higher-order Reed-Muller encoder (using parameters X and “#_ACK/NACK” as described above, for example) to produce encoded ACK/NACK bits 1042 with repeated parity bits. The Reed-Muller encoder may use circular repetition to produce the repeated parity bits.

The UE 102 may determine 1106 whether there is a current scheduling request (e.g., SRI=1). If the UE 102 determines 1106 that there is no current scheduling request (e.g., SRI=0), then the UE 102 may transmit 1110 the jointly-encoded SRI and ACK/NACK message 1032 (without modifying the repeated parity bits, for example). It should be noted that the message may be deemed a “jointly-encoded SRI and ACK/NACK message” 1032, even though no modification has been made to the repeated parity bits, since this implicitly indicates that there is no current scheduling request (e.g., SRI=0). In other words, the jointly-encoded SRI and ACK/NACK message 1032 may comprise the encoded ACK/NACK bits 1042 with the unmodified repeated parity bits when there is no scheduling request (e.g., SRI=0).

If the UE 102 determines 1106 that there is a current scheduling request (e.g., SRI=1), the UE 102 may invert (e.g., “flip”) 1108 a number (e.g., 0, 1 or more) of the repeated parity bits. For example, the UE 102 may change each ‘0’ bit in the repeated parity bits to a ‘1’ bit and may change each ‘1’ bit in the repeated parity bits to a ‘0’ bit. In alternative configurations, zero or a subset of the repeated parity bits may be inverted 1108 or more than the repeated parity bits (e.g., a number of the last bits in the jointly-encoded message 1032) may be inverted 1108. Encoding the SRI bit 1022 and ACK/NACK bits 1024 in this way may provide unequal error protection by providing greater or lesser reliability (e.g., greater or lesser redundancy) to the SRI than to each ACK/NACK. In one instance, this may provide the benefit that the SRI information is more reliably received by a Node B 110, thus allowing the Node B 110 to schedule or prepare to schedule resources for the UE 102. Alternatively, this may provide the benefit that the ACK/NACK information is more reliably received than the SRI information, thus allowing the Node B to more reliably detect ACK/NACK information.

The UE 102 may then transmit 1110 the jointly-encoded SRI and ACK/NACK message 1032 (comprising, for example, the encoded ACK/NACK bits 1042 with inverted repeated parity bits). For example, the UE 102 may transmit 1110 the joint message 1032 on a PUCCH 114 using one or more antennas 106a-n.

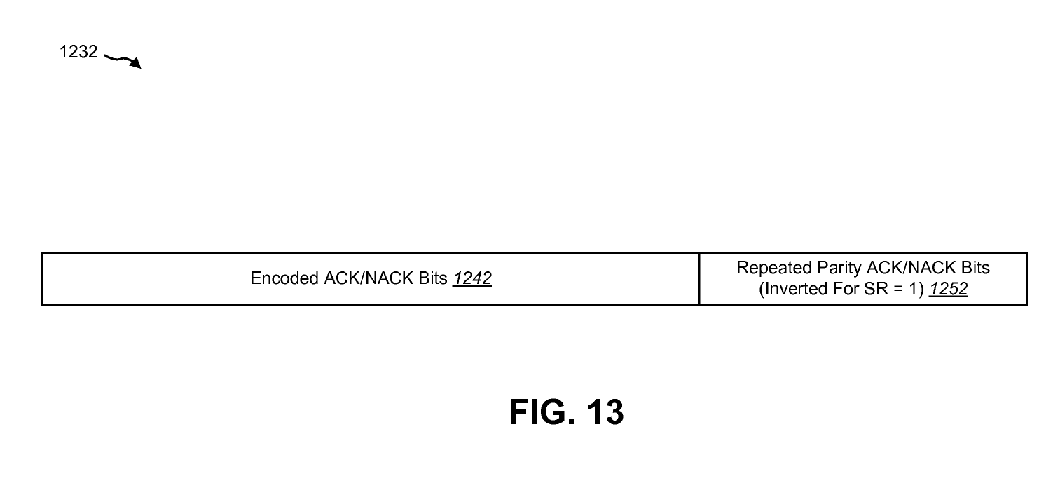

FIG. 13 is a diagram illustrating one example of a jointly-encoded Scheduling Request Indicator (SRI) and Acknowledgment/Negative Acknowledgment (ACK/NACK) message 1232. More specifically, FIG. 13 illustrates one example of a jointly-encoded SRI and ACK/NACK message 1232 that may be generated according to the method 1100 illustrated in FIG. 12.

For example, a Reed-Muller encoding module 1040 may generate the encoded ACK/NACKs 1242 using input ACK/NACKs 1024. The Reed-Muller encoding module 1040 may generate a number of repeated ACK/NACK parity bits 1252. As described above, the implicit SRI encoding module 1050 may invert zero, one or more of the repeated ACK/NACK parity bits 1252 when there is a current scheduling request (e.g., SRI=1). For example, none or a subset of the repeated parity bits 1252 may be inverted or more than the repeated parity bits 1252 (e.g., a number of the last bits in the jointly-encoded message 1232) may be inverted. The implicit SRI encoding module 1050 may not modify the repeated ACK/NACK parity bits 1252 when there is no current scheduling request (e.g., SRI=0).

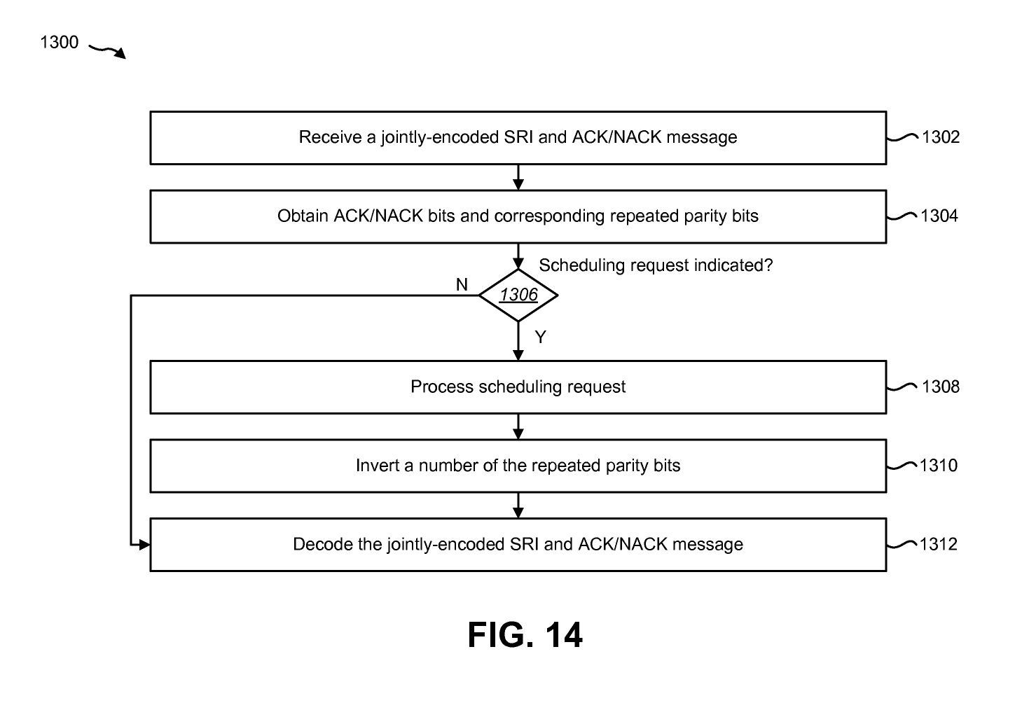

FIG. 14 is a flow diagram illustrating one configuration of a method 1300 for decoding a jointly-encoded Scheduling Request Indicator (SRI) and Acknowledgement/Negative Acknowledgment (ACK/NACK) message. More specifically, FIG. 14 illustrates a method for decoding a jointly-encoded SRI and ACK/NACK message when the message is jointly encoded as illustrated in FIGS. 10, 11 and 12.

A Node B 110 (e.g., a joint SRI and ACK/NACK decoding module 112) may receive 1302 a jointly-encoded SRI and ACK/NACK message 1032, 1232. For example, the Node B 110 may receive the jointly-encoded message 1032, 1232 using one or more antennas 108a-n.

The Node B 110 may optionally obtain 1304 ACK/NACK bits and corresponding repeated parity bits. For example, the repeated parity bits are a repetition of a number of (encoded) ACK/NACK bits. The Node B 110 may separate or distinguish the (encoded) ACK/NACK bits and their repeated parity bits from other bits (if any) in the jointly-encoded message 1032, 1232.

The Node B 110 may determine 1306 whether a scheduling request is indicated by the jointly-encoded message 1032, 1232. For example, the decoder (e.g., joint SRI and ACK/NACK decoding module 112) can detect the SR transmission based on the joint detection of SR and ACK/NACK. In one configuration, the decoder may blindly decode under both hypotheses to decide whether a positive SRI is indicated. The decoder can use the first 16 bits and the last 16 bits from the demodulated data to determine 1306 whether it is a positive or negative SR.

In one configuration, the Node B 110 compares the (encoded) ACK/NACK bits to the repeated parity bits. For example, if a number of inverted (in comparison to the corresponding ACK/NACK bits) repeated parity bits is greater than a threshold number, the Node B 110 may determine 1306 that a scheduling request was indicated by the UE 102. Alternatively, using the first and last M bits (where M≦16, for example), the UE 102 may compute a log likelihood ratio under the hypothesis of no SR or positive SR and choose the one that has a higher likelihood to indicate positive (or negative) SR.

It should be noted that one or more of the repeated parity bits may be inverted as a result of being incorrectly received. However, in some configurations, this determination 1306 may be based on the likelihood of a certain number of bits or a certain proportion of bits being inverted. For instance, a small number or portion of the repeated parity bits (or the corresponding ACK/NACK bits) may be received incorrectly, resulting in a small number of inverted bits when comparing the two. However, this may not indicate that the UE 102 is implicitly indicating a scheduling request (e.g., SRI=1). If a larger number or portion of the repeated parity bits are inverted in comparison, however, this may indicate that the UE 102 is implicitly indicating a current scheduling request (e.g., SRI=1). Thus, the Node B 110 may determine 1306 whether the jointly-encoded message 1032, 1232 indicated a scheduling request (e.g., SRI=1) or not (e.g., SRI=0).

If the Node B 110 determines 1306 that no scheduling request is indicated, the Node B 110 may decode 1312 the jointly-encoded SRI and ACK/NACK message 1032, 1232. The decoded message may be used to determine whether to resend one or more incorrectly received packets, for example.

If the Node B 110 determines that the jointly-encoded message 1032, 1232 indicates a scheduling request, the Node B 110 may process 1308 a scheduling request. For example, the Node B 110 may allocate resources for the UE 102 or may prepare to allocate resources or receive more information about the resources needed from the UE 102.

The Node B 110 may invert 1310 a number (e.g., 0, 1 or more) of the repeated parity bits. For instance, the last 16 bits may be (re)inverted 1310 to restore the repeated parity bits to their original sequence (since they were inverted to indicate a positive SRI). In alternative configurations, a subset of the repeated parity bits or more than the repeated parity bits may be inverted, depending on which bits are inverted to indicate a positive SRI. The Node B 110 may then decode 1312 the jointly-encoded SRI and ACK/NACK message 1032, 1232. For example, the decoder may decode the 48 bit encoded data. The decoded message may be used to determine whether to resend one or more incorrectly received packets, for example.

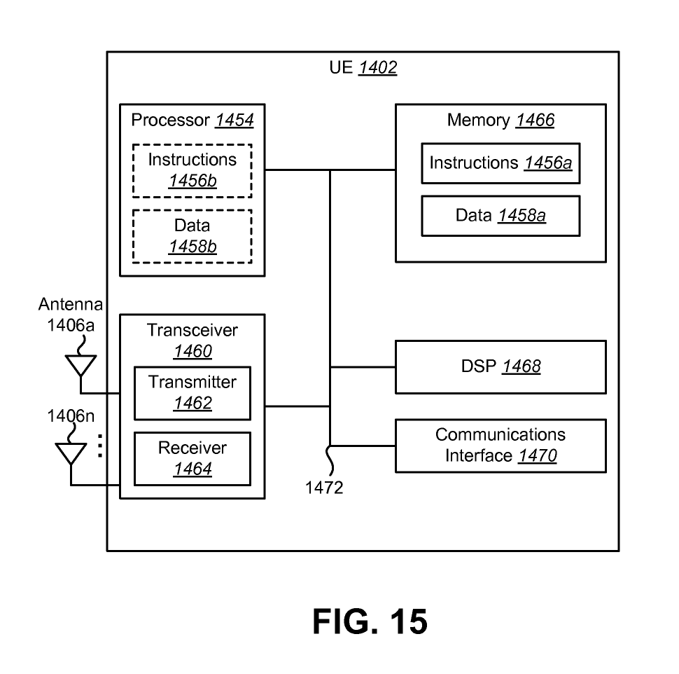

FIG. 15 illustrates various components that may be utilized in a User Equipment (UE) 1402. The UE 1402 may be utilized as the UE 102 illustrated previously. The UE 1402 includes a processor 1454 that controls operation of the UE 1402. The processor 1454 may also be referred to as a CPU. Memory 1466, which may include read-only memory (ROM), random access memory (RAM), a combination of the two or any type of device that may store information, provides instructions 1456a and data 1458a to the processor 1454. A portion of the memory 1466 may also include non-volatile random access memory (NVRAM). Instructions 1456b and data 1458b may also reside in the processor 1454. Instructions 1456b and/or data 1458b loaded into the processor 1454 may also include instructions 1456a and/or data 1458a from memory 1466 that were loaded for execution or processing by the processor 1454. The instructions 1456b may be executed by the processor 1454 to implement the systems and methods disclosed herein.

The UE 1402 may also include a housing that contains a transmitter 1462 and a receiver 1464 to allow transmission and reception of data. The transmitter 1462 and receiver 1464 may be combined into a transceiver 1460. One or more antennas 1406a-n are attached to the housing and electrically coupled to the transceiver 1460.

The various components of the UE 1402 are coupled together by a bus system 1472 which may include a power bus, a control signal bus, and a status signal bus, in addition to a data bus. However, for the sake of clarity, the various buses are illustrated in FIG. 15 as the bus system 1472. The UE 1402 may also include a digital signal processor (DSP) 1468 for use in processing signals. The UE 1402 may also include a communications interface 1470 that provides user access to the functions of the UE 1402. The UE 1402 illustrated in FIG. 15 is a functional block diagram rather than a listing of specific components.

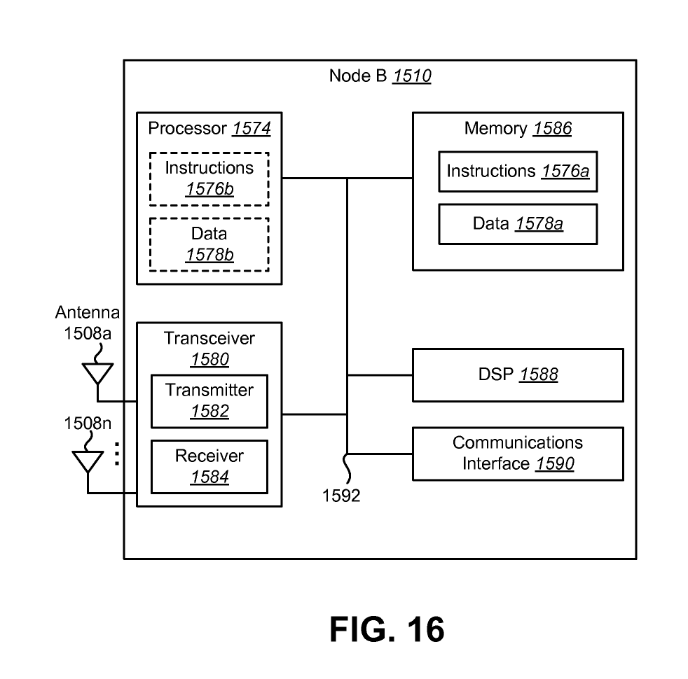

FIG. 16 illustrates various components that may be utilized in a Node B 1510. The Node B 1510 may be utilized as the Node B 110 illustrated previously. The Node B 1510 may include components that are similar to the components discussed above in relation to the UE 1402, including a processor 1574, memory 1586 that provides instructions 1576a and data 1578a to the processor 1574, instructions 1576b and data 1578b that may reside in or be loaded into the processor 1574, a housing that contains a transmitter 1582 and a receiver 1584 (which may be combined into a transceiver 1580), one or more antennas 1508a-n electrically coupled to the transceiver 1580, a bus system 1592, a DSP 1588 for use in processing signals, a communications interface 1590 and so forth.

The term “computer-readable medium” refers to any available medium that can be accessed by a computer or a processor. The term “computer-readable medium,” as used herein, may denote a computer- and/or processor-readable medium that is non-transitory and tangible. By way of example, and not limitation, a computer-readable or processor-readable medium may comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer or processor. Disk and disc, as used herein, includes compact disc (CD), laser disc, optical disc, digital versatile disc (DVD), floppy disk and Blu-ray® disc where disks usually reproduce data magnetically, while discs reproduce data optically with lasers.

Each of the methods disclosed herein comprises one or more steps or actions for achieving the described method. The method steps and/or actions may be interchanged with one another and/or combined into a single step without departing from the scope of the claims. In other words, unless a specific order of steps or actions is required for proper operation of the method that is being described, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A User Equipment (UE) configured for jointly encoding a Scheduling Request Indicator (SRI) and Acknowledgments/Negative Acknowledgments (ACK/NACKs), comprising:
a processor;
memory in electronic communication with the processor;
instructions stored in the memory, the instructions being executable to:
generate a Scheduling Request Indicator (SRI) bit and a plurality of Acknowledgement/Negative Acknowledgement (ACK/NACK) bits;
encode the SRI bit and the plurality of ACK/NACK bits with unequal error protection to generate a jointly-encoded SRI and ACK/NACK message; and
transmit the jointly-encoded SRI and ACK/NACK message.

2. The UE of claim 1, wherein unequal error protection is provided by providing more protection to the SRI bit than to each of the ACK/NACK bits.

3. The UE of claim 1, wherein unequal error protection is provided by providing more protection to each of the ACK/NACK bits than to the SRI bit.

4. The UE of claim 1, wherein encoding the SRI bit and the plurality of ACK/NACK bits comprises:
encoding the SRI bit to produce a number of encoded SRI bits; and
encoding the encoded SRI bits and the plurality of ACK/NACK bits using a Reed-Muller encoder.

5. The UE of claim 4, wherein the SRI bit is encoded using repetition encoding.

6. The UE of claim 4, wherein the SRI bit is encoded using Reed-Muller encoding.

7. The UE of claim 1, wherein encoding the SRI bit and the plurality of ACK/NACK bits comprises:
encoding the SRI bit to produce a number of encoded SRI bits;
encoding the plurality of ACK/NACK bits using a Reed-Muller encoder to produce encoded ACK/NACK bits; and
combining the encoded SRI bits and the encoded ACK/NACK bits.

8. The UE of claim 7, wherein the SRI bit is encoded using repetition encoding.

9. The UE of claim 7, wherein the SRI bit is encoded using Reed-Muller encoding.

10. The UE of claim 1, wherein encoding the SRI bit and the plurality of ACK/NACK bits comprises:
encoding the SRI bit to produce a number of encoded SRI bits;
encoding the plurality of ACK/NACK bits using a Reed-Muller encoder to produce encoded ACK/NACK bits; and
combining the encoded SRI bits and the encoded ACK/NACK bits by placing one or more encoded SRI bits in place of one or more generated repeated parity bits or in place of one or more repeated parity bits that are not generated.

11. The UE of claim 10, wherein the SRI bit is encoded using repetition encoding.

12. The UE of claim 10, wherein the SRI bit is encoded using Reed-Muller encoding.

13. The UE of claim 1, wherein encoding the SRI bit and the plurality of ACK/NACK bits comprises:
encoding the plurality of ACK/NACK bits using a Reed-Muller encoder to produce encoded ACK/NACK bits with repeated parity bits;
determining whether the SRI bit indicates a Scheduling Request (SR); and
inverting a number of the repeated parity bits if the SRI bit indicates an SR.

14. A Node B for decoding a jointly-encoded Scheduling Request Indicator (SRI) and Acknowledgment/Negative Acknowledgment (ACK/NACK) message, comprising:
a processor;
memory in electronic communication with the processor;
instructions stored in the memory, the instructions being executable to:
receive a jointly-encoded SRI and ACK/NACK message;
determine whether the jointly-encoded SRI and ACK/NACK message indicates a scheduling request;
invert a number of repeated parity bits if the jointly-encoded SRI and ACK/NACK message indicates a scheduling request; and
decode the jointly-encoded SRI and ACK/NACK message.

15. A method for jointly encoding a Scheduling Request Indicator (SRI) and Acknowledgments/Negative Acknowledgments (ACK/NACKs), comprising:
generating a Scheduling Request Indicator (SRI) bit and a plurality of Acknowledgement/Negative Acknowledgement (ACK/NACK) bits;
encoding, on a User Equipment (UE), the SRI bit and the plurality of ACK/NACK bits with unequal error protection to generate a jointly-encoded SRI and ACK/NACK message; and
transmitting the jointly-encoded SRI and ACK/NACK message.

16. The method of claim 15, wherein unequal error protection is provided by providing more protection to the SRI bit than each of the ACK/NACK bits.

17. The method of claim 15, wherein unequal error protection is provided by providing more protection to each of the ACK/NACK bits than to the SRI bit.

18. The method of claim 15, wherein encoding the SRI bit and the plurality of ACK/NACK bits comprises:
encoding the SRI bit to produce a number of encoded SRI bits; and
encoding the encoded SRI bits and the plurality of ACK/NACK bits using a Reed-Muller encoder.

19. The method of claim 18, wherein the SRI bit is encoded using repetition encoding.

20. The method of claim 18, wherein the SRI bit is encoded using Reed-Muller encoding.

21. The method of claim 15, wherein encoding the SRI bit and the plurality of ACK/NACK bits comprises:
encoding the SRI bit to produce a number of encoded SRI bits;
encoding the plurality of ACK/NACK bits using a Reed-Muller encoder to produce encoded ACK/NACK bits; and
combining the encoded SRI bits and the encoded ACK/NACK bits.

22. The method of claim 21, wherein the SRI bit is encoded using repetition encoding.

23. The method of claim 21, wherein the SRI bit is encoded using Reed-Muller encoding.

24. The method of claim 15, wherein encoding the SRI bit and the plurality of ACK/NACK bits comprises:
encoding the SRI bit to produce a number of encoded SRI bits;
encoding the plurality of ACK/NACK bits using a Reed-Muller encoder to produce encoded ACK/NACK bits; and
combining the encoded SRI bits and the encoded ACK/NACK bits by placing one or more encoded SRI bits in place of one or more generated repeated parity bits or in place of one or more repeated parity bits that are not generated.

25. The method of claim 24, wherein the SRI bit is encoded using repetition encoding.

26. The method of claim 24, wherein the SRI bit is encoded using Reed-Muller encoding.

27. The method of claim 15, wherein encoding the SRI bit and the plurality of ACK/NACK bits comprises:
encoding the plurality of ACK/NACK bits using a Reed-Muller encoder to produce encoded ACK/NACK bits with repeated parity bits;
determining whether the SRI bit indicates a Scheduling Request (SR); and
inverting a number of the repeated parity bits if the SRI bit indicates an SR.

28. A method for decoding a jointly-encoded Scheduling Request Indicator (SRI) and Acknowledgment/Negative Acknowledgment (ACK/NACK) message, comprising:
receiving a jointly-encoded SRI and ACK/NACK message;
determining, on a Node B, whether the jointly-encoded SRI and ACK/NACK message indicates a scheduling request;
inverting, on the Node B, a number of repeated parity bits if the jointly-encoded SRI and ACK/NACK message indicates a scheduling request; and
decoding the jointly-encoded SRI and ACK/NACK message.

29. A non-transitory, tangible computer-readable medium for jointly encoding a Scheduling Request Indicator (SRI) and Acknowledgments/Negative Acknowledgments (ACK/NACKs), comprising executable instructions for:
generating a Scheduling Request Indicator (SRI) bit and a plurality of Acknowledgement/Negative Acknowledgement (ACK/NACK) bits;
encoding the SRI bit and the plurality of ACK/NACK bits with unequal error protection to generate a jointly-encoded SRI and ACK/NACK message; and
transmitting the jointly-encoded SRI and ACK/NACK message.

30. A non-transitory, tangible computer-readable medium for decoding a jointly-encoded Scheduling Request Indicator (SRI) and Acknowledgment/Negative Acknowledgment (ACK/NACK) message, comprising executable instructions for:
receiving a jointly-encoded SRI and ACK/NACK message;
determining whether the jointly-encoded SRI and ACK/NACK message indicates a scheduling request;
inverting a number of repeated parity bits if the jointly-encoded SRI and ACK/NACK message indicates a scheduling request; and
decoding the jointly-encoded SRI and ACK/NACK message.
